(19) United States
(12) Patent Application Publication
(10) Pub. No.: US 2026/0303115 A1
(43) Pub. Date: Oct. 1, 2026

(54) METHODS AND APPARATUS TO COMPENSATE FOR NON-LINEARITY IN INTERLEAVED DIGITAL-TO-ANALOG CONVERTERS

(71) Applicant: Texas Instruments Incorporated, Dallas, TX (US)

(72) Inventors: Snehasish Roychowdhury, Dakshin Barasat (IN); Visvesvaraya Appala Pentakota, Bangalore (IN)

(21) Appl. No.: 19/095,618

(22) Filed: Mar. 31, 2025

(51) Int. Cl. H03M 1/66; H03M 1/06

(52) U.S. Cl. CPC H03M 1/662; H03M 1/0614

(57) ABSTRACT

An example apparatus includes a multiplexer having a first output and a second output. The apparatus includes a first capacitor having a first terminal and a second terminal coupled to the first output of the multiplexer. The apparatus includes a first lead compensator (LC) circuit having an output and an input coupled to the first terminal of the first capacitor. The apparatus includes a first resistor having a first terminal coupled to the output of the first LC circuit and a second terminal coupled to a first supply terminal. The apparatus includes a first transistor having a control terminal, a first terminal, and a second terminal, the control terminal coupled to the output of the first LC circuit, the second terminal coupled to a ground terminal. The apparatus includes a second transistor having a control terminal coupled to a second supply terminal, a first terminal coupled to the second output of the multiplexer, and a second terminal coupled to the first terminal of the first transistor. The apparatus includes a first current source circuit having an output coupled to the ground terminal and an input coupled to the second terminal of the second transistor. The apparatus includes a second capacitor having a first terminal and a second terminal coupled to the second output of the multiplexer. The apparatus includes a second LC circuit having an output and an input coupled to the first terminal of the second capacitor. The apparatus includes a second resistor having a first terminal coupled to the output of the second LC circuit and a second terminal coupled to the first supply terminal. The apparatus includes a third transistor having a control terminal, a first terminal, and a second terminal, the control terminal coupled to the output of the second LC circuit, the second terminal coupled to the ground terminal. The apparatus includes a fourth transistor having a control terminal coupled to the second supply terminal, a first terminal coupled to the first output of the multiplexer, and a second terminal coupled to the first terminal of the third transistor. The apparatus includes a second current source circuit having an output coupled to the ground terminal and an input coupled to the second terminal of the fourth transistor.

### TECHNICAL FIELD

This description relates generally to digital-to-analog converters and, more particularly, to methods and apparatus to compensate for non-linearity in interleaved digital-to-analog converters.

### BACKGROUND

In electronics, a digital-to-analog converter (DAC) is a circuit that converts a digital signal into an analog signal. An analog-to-digital converter (ADC) is a circuit that converts an analog signal to a digital signal. DACs and ADCs are utilized in a variety of applications such as audio, video, control, instrumentation, data acquisition, communication, imaging, automotive, and aerospace applications, among other applications. In communication applications, for example, DACs are utilized to convert digitally defined signals into analog signals for transmission over a wired or wireless communication medium. There are many architectures according to which a DAC can be implemented depending on the application in which the DAC is utilized. For example, the suitability of a DAC architecture for a particular application is determined according to performance characteristics such as resolution and maximum sampling frequency, among others.

### SUMMARY

For methods and apparatus to compensate for non-linearity in interleaved digital-to-analog converters, an example apparatus includes a multiplexer having a first output and a second output. The apparatus includes a first capacitor having a first terminal and a second terminal coupled to the first output of the multiplexer. The apparatus includes a first lead compensator (LC) circuit having an output and an input coupled to the first terminal of the first capacitor. The apparatus includes a first resistor having a first terminal coupled to the output of the first LC circuit and a second terminal coupled to a first supply terminal. The apparatus includes a first transistor having a control terminal, a first terminal, and a second terminal, the control terminal coupled to the output of the first LC circuit, the second terminal coupled to a ground terminal. The apparatus includes a second transistor having a control terminal coupled to a second supply terminal, a first terminal coupled to the second output of the multiplexer, and a second terminal coupled to the first terminal of the first transistor. The apparatus includes a first current source circuit having an output coupled to the ground terminal and an input coupled to the second terminal of the second transistor. The apparatus includes a second capacitor having a first terminal and a second terminal coupled to the second output of the multiplexer. The apparatus includes a second LC circuit having an output and an input coupled to the first terminal of the second capacitor. The apparatus includes a second resistor having a first terminal coupled to the output of the second LC circuit and a second terminal coupled to the first supply terminal. The apparatus includes a third transistor having a control terminal, a first terminal, and a second terminal, the control terminal coupled to the output of the second LC circuit, the second terminal coupled to the ground terminal. The apparatus includes a fourth transistor having a control terminal coupled to the second supply terminal, a first terminal coupled to the first output of the multiplexer, and a second terminal coupled to the first terminal of the third transistor. The apparatus includes a second current source circuit having an output coupled to the ground terminal and an input coupled to the second terminal of the fourth transistor. Other examples are described.

For methods and apparatus to compensate for non-linearity in interleaved digital-to-analog converters, an example digital-to-analog converter (DAC). The DAC includes control circuitry having a first terminal, a second terminal, a third terminal, and a fourth terminal. The DAC includes a first switch having a control terminal, a first terminal, and a second terminal, the control terminal coupled to the first terminal of the control circuitry. The DAC includes a first DAC core having a positive output, a negative output, and an input coupled to the second terminal of the first switch. The DAC includes a second switch having a control terminal, a first terminal, and a second terminal, the control terminal coupled to the second terminal of the control circuitry, the first terminal coupled to the first terminal of the first switch. The DAC includes a second DAC core having a positive output, a negative output, and an input coupled to the second terminal of the second switch. The DAC includes a multiplexer having a positive output, a negative output, a first positive input coupled to the positive output of the first DAC core, a first negative input coupled to the negative output of the first DAC core, a second positive input coupled to the positive output of the second DAC core, a second negative input coupled to the negative output of the second DAC core, a first control terminal coupled to the third terminal of the control circuitry, and a second control terminal coupled to the fourth terminal of the control circuitry. The DAC includes an output termination network having a positive input coupled to the positive output of the multiplexer and a negative input coupled to the negative output of the multiplexer. The DAC includes a compensation network having a positive input coupled to the positive output of the multiplexer, a negative input coupled to the negative output of the multiplexer, a positive supply terminal coupled to the negative output of the multiplexer, and a negative supply terminal coupled to the positive output of the multiplexer. Other examples are described.

For methods and apparatus to compensate for non-linearity in interleaved digital-to-analog converters, an example apparatus includes a multiplexer having a positive output and a negative output. The apparatus includes a first capacitor having a first terminal and a second terminal coupled to the positive output of the multiplexer. The apparatus includes a first lead compensator (LC) circuit having an output and an input coupled to the first terminal of the first capacitor. The apparatus includes a second capacitor having a first terminal and a second terminal coupled to the positive output of the multiplexer. The apparatus includes a second LC circuit having an output and an input coupled to the first terminal of the second capacitor. The apparatus includes a first cancellation circuit having a first input coupled to the output of the first LC circuit, a second input coupled to the output of the second LC circuit, a first voltage terminal coupled to the negative output of the multiplexer, and a second voltage terminal coupled to a ground terminal. The apparatus includes a third capacitor having a first terminal and a second terminal coupled to the negative output of the multiplexer. The apparatus includes a third LC circuit having an output and an input coupled to the first terminal of the third capacitor. The apparatus includes a fourth capacitor having a first terminal and a second terminal coupled to the negative output of the multiplexer. The apparatus includes a fourth LC circuit having an output and an input coupled to the first terminal of the fourth capacitor. The apparatus includes a second cancellation circuit having a first input coupled to the output of the third LC circuit, a second input coupled to the output of the fourth LC circuit, a first voltage terminal coupled to the positive output of the multiplexer, and a second voltage terminal coupled to the ground terminal. Other examples are described.

### BRIEF DESCRIPTION OF THE DRAWINGS

FIG. 1 is a block diagram of an example radio frequency (RF) integrated circuit (IC).

FIG. 2 is a block diagram of an example digital-to-analog converter (DAC) that can implement one or more of the DACs of FIG. 1.

FIG. 3 is schematic diagram of example implementations of the DAC cores, the differential multiplexer, and the output termination network of FIG. 2.

FIG. 4 is a schematic diagram of an example compensation circuit with one input and one supply terminal that can implement the compensation network of FIG. 2.

FIG. 5 is a schematic diagram of an example implementation of the compensation circuit of FIG. 4 including a first example lead compensator (LC) circuit and a second example LC circuit.

FIG. 6 is a schematic diagram of an example implementation of the compensation network of FIG. 2.

FIG. 7 is schematic diagram of an example lead compensator (LC) circuit that can implement one or more of the LC circuits of FIG. 5 or one or more of the LC circuits of FIG. 6.

FIG. 8A is a graphical illustration of an example plot including an example magnitude response of the LC circuit of FIG. 7.

FIG. 8B is a graphical illustration of an example plot including an example phase response of the LC circuit of FIG. 7.

FIG. 8C is a graphical illustration of an example plot including a first example phase response of the DAC of FIG. 2 with the LC circuits of FIG. 6 and a second example phase response of the DAC of FIG. 2 without the LC circuits of FIG. 6.

The drawings are not necessarily to scale. Generally, the same reference numbers in the drawing(s) and this description refer to the same or similar (in terms of at least one of functional or structural) features or parts. Although the drawings show regions with clean lines and boundaries, some or all of these lines and boundaries may be idealized. In reality, the boundaries or lines may be unobservable, blended or irregular.

### DETAILED DESCRIPTION

Modern radio frequency (RF) applications include communication and radar applications. Other RF applications include defense such as munitions guidance, motor control feedback, network and vector analyzers, communications test equipment, nondestructive testing, microwave receivers, software-defined radios, quadrature and diversity radio receivers, and handheld radio and instrumentation. In modern applications, RF circuits operate in a variety of frequency ranges. Even within a particular application, operating frequencies of RF circuits can vary.

For example, while RF circuits in communication applications generally operate between 20 kilohertz (kHz) and 300 gigahertz (GHz), RF circuits in satellite communication applications operate between 2 GHz and 30 GHz. Also, in multi-carrier, multi-mode cellular communication applications, RF circuits can support multiple bands, such as dual-band, tri-band, quad-band, etc., with center frequencies ranging from 800 MHz to 2.1 GHz. In smart antenna communication applications, RF circuits can support fourth generation (4G) communication (600 MHz-2.6 GHz), fifth generation (5G) communication (<1 GHz-40 GHz), and sixth generation (6G) communication (7 GHz-300 GHz).

To support higher operating frequencies, some DACs implement interleaving. For example, a DAC operates by converting discrete values representing a digital signal into a continuous or approximately continuous analog signal. In some examples, the DAC is described as sampling the digital signal (e.g., the discrete values). In a DAC implementing interleaving, the DAC utilizes two or more sub-DACs (also referred to as DAC cores) coupled to a switching circuit (such as a multiplexer). The outputs of the two or more sub-DACs are coupled to the switching circuit to interleave samples generated by the two or more sub-DACs. By sequencing, with the switching circuit, samples generated by the two or more sub-DACs, the DAC generates an analog signal with a higher sampling rate than the sampling rates of the two or more sub-DACs. In this manner, an interleaved DAC can generate higher frequency analog signals than a non-interleaved DAC by generating relatively more samples to create an analog signal.

To implement a 64 giga-sample-per-second (GSPS) DAC with interleaving, the DAC is implemented using eight time-interleaved (TI) DAC cores where each DAC core samples a 12-bit digital signal at 8 GSPS. As such, a 64 GSPS DAC can operate across a bandwidth of 18 GHz. To operate in a variety of applications described herein, a 64 GSPS DAC has a target spurious-free dynamic range (SFDR) of greater than 55 decibels relative to a carrier signal (dBc) across the input frequency range of the 64 GSPS DAC. As used herein, SFDR refers to the ratio between the root mean square (RMS) value of a carrier signal at the output of a DAC and the RMS value of the next largest noise or harmonic distortion component at the output of the DAC.

In an interleaved DAC, each DAC core includes a pair of transconductance (gₘ) transistors to set the current in respective analog output signals generated by the DAC cores. Also, the pair of gₘ transistors are source degenerated meaning that the source terminal of each of the gₘ transistors is coupled to a ground terminal via a resistor. Including source degenerated gₘ transistors in each DAC core can reduce non-linear distortion in the analog output signals from the DAC cores. However, despite including source degenerated gₘ transistors in each DAC core, non-linearities introduced by the gₘ transistors are the dominant contributor to the overall non-linearity in the analog output signal from the interleaved DAC. Example non-linearities include in-phase (I) and quadrature (Q) components of third-order intermodulation distortion (IMD₃) components and third-order harmonic distortion (HD₃) components across the intermediate frequency (IF) in RF applications. IMD₃ components are present, for example, up to 6 GHz and HD₃ components are present, for example, between 3 GHz and 18 GHz.

To cancel out non-linearities, each DAC core includes an auxiliary pair of gₘ transistors that are biased in a weak inversion region that is opposite of the biasing of the main pair of gₘ transistors of the DAC core. By including an auxiliary pair of gₘ transistors in each DAC core, each DAC core cancels out the IMD₃ components of the main pair of gₘ transistors. For example, the absolute value of the third-order transconductance of the main pair of gₘ transistors is equal to the absolute value of the third-order transconductance of the auxiliary pair of gₘ transistors. As such, there is no relative phase shift at the inputs of each DAC core.

However, including an auxiliary pair of gₘ transistors in each DAC core does not provide compensation for non-linearities across the full bandwidth of the interleaved DAC. For example, including an auxiliary pair of gₘ transistors in each DAC core reduces IMD₃ components but not HD₃ components, and both non-linearities are present up to 6 GHz in the bandwidth of a 64 GSPS DAC. Also, including an auxiliary pair of gₘ transistors and associated circuitry in each DAC core consumes a large amount of area on a chip. Including an auxiliary pair of gₘ transistors and associated circuitry in each DAC core also increases the non-linear capacitive load at the input of the DAC which results in a worse intrinsic linearity characteristic for an interleaved DAC. Also, including an auxiliary pair of gₘ transistors and associated circuitry in each DAC core adds to the complexity of routing and placement of components in a chip.

Furthermore, if the thermal voltage (V_{T}) of auxiliary pairs of gₘ transistors across DAC cores is mismatched, then compensation of IMD₃ components, a frequency dependent term, will be different in each DAC core. For example, while interleaved signal spurs in the fundamental band of the analog output signal from an interleaved DAC will cancel out, the IMD₃ components in frequency bands adjacent to the fundamental band will not cancel out due to the mismatch between DAC cores. As such, if the thermal voltage of auxiliary pairs of gₘ transistors across DAC cores is mismatched, then interleaving introduces IMD₃ components in the analog output signal from an interleaved DAC instead of fully cancelling such non-linearities.

Examples described herein include an example compensation network at the output of a switching circuit (for example, a differential multiplexer) in an interleaved DAC. For example, the compensation network includes a single pair of compensation transistors (and associated circuitry) that senses an analog output signal from the switching circuit and mitigates non-linearities in the analog output signal. For example, the single pair of compensation transistors at the output of the switching circuit mitigates both IMD₃ and HD₃ components between 0 hertz (Hz) and 3 GHz and between 6 GHz and 18 GHz in the bandwidth of a 64 GSPS DAC. Also, examples described herein include a lead compensation circuit that provides additional compensation for both IMD₃ and HD₃ components between 3 GHz and 6 GHz in the bandwidth of a 64 GSPS DAC.

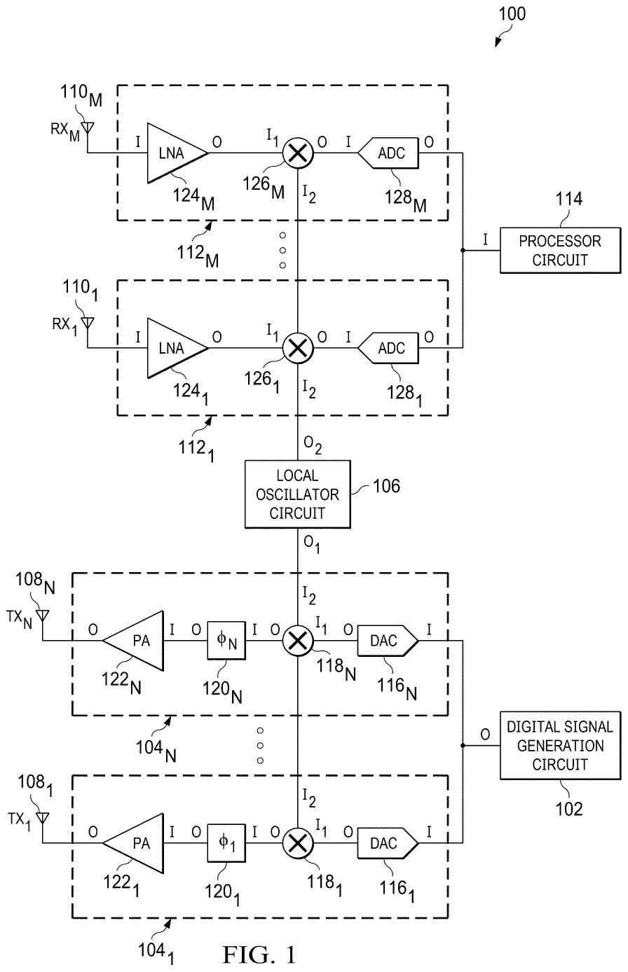

FIG. 1 is a block diagram of an example radio frequency (RF) integrated circuit (IC) 100. In the example of FIG. 1, the RF IC 100 includes an example digital signal generation circuit 102, example transmitters 104₁-104_{N}, an example local oscillator circuit 106, example transmit antennas 108₁-108_{N}, example receive antennas 110₁-110_{M}, example receivers 112₁-112_{M}, and an example processor circuit 114. Also, in the example of FIG. 1, the transmitters 104₁-104_{N} include example digital-to-analog converters (DACs) 116₁-116_{N}, first example mixers 118₁-118_{N}, example phase shifters 120₁-120_{N}, and example power amplifiers (PAs) 122₁-122_{N}, respectively.

In the illustrated example of FIG. 1, the receivers 112₁-112_{M} include example low noise amplifiers (LNAs) 124₁-124_{M}, second example mixers 126₁-126_{M}, and example analog-to-digital converters (ADCs) 128₁-128_{M}, respectively. In the example of FIG. 1, the RF IC 100 includes sixteen of each of the transmitters 104₁-104_{N} and the transmit antennas 108₁-108_{N}.

For example, N equals sixteen. In the example of FIG. 1, the RF IC 100 includes sixteen of each of the receive antennas 110₁-110_{M} and the receivers 112₁-112_{M}. For example, M equals sixteen. In some examples, the RF IC 100 includes a different numbers of any of the transmitters 104₁-104_{N}, the transmit antennas 108₁-108_{N}, the receive antennas 110₁-110_{M}, or the receivers 112₁-112_{M}.

In some examples, the RF IC 100 and the processor circuit 114 are implemented separately and may be coupled together. Also or alternatively, the RF IC 100 is implemented with the processor circuit 114, for example, in a single chip package or on a system on chip (SoC) (for example, a single IC). In examples where the RF IC 100 is implemented with the processor circuit 114 on a SoC, the RF IC 100 may correspond to a sub-circuit of the IC that forms the SoC.

In the illustrated example of FIG. 1, each of the DACs 116₁-116_{N}, each of the phase shifters 120₁-120_{N}, each of the PAs 122₁-122_{N}, each of the LNAs 124₁-124_{M}, and each of the ADCs 128₁-128_{M} has an input and an output. In the example of FIG. 1, each of the mixers 118₁-118_{N} and each of the mixers 126₁-126_{M} has a first input, a second input, and an output. Also, the digital signal generation circuit 102 has an output, the local oscillator circuit 106 has a first output and a second output, and the processor circuit 114 has an input.

In the illustrated example of FIG. 1, the digital signal generation circuit 102 is implemented by at least one of analog circuitry or digital circuitry. In the example of FIG. 1, the digital signal generation circuit 102 is coupled to the transmitters 104₁-104_{N}. For example, the output of the digital signal generation circuit 102 is coupled to respective inputs of the DACs 116₁-116_{N} of the transmitters 104₁-104_{N}. In some examples, the digital signal generation circuit 102 is coupled to the processor circuit 114.

In the illustrated example of FIG. 1, each of the DACs 116₁-116_{N} is implemented by at least one of analog circuitry or digital circuitry. In the example of FIG. 1, the DACs 116₁-116_{N} are coupled to the digital signal generation circuit 102. For example, the input of respective DACs is coupled to the output of the digital signal generation circuit 102. Also, in the example of FIG. 1, the DACs 116₁-116_{N} are coupled to the mixers 118₁-118_{N}. For example, the output of respective DACs is coupled to the first input of respective mixers.

In the illustrated example of FIG. 1, each of the mixers 118₁-118_{N} is implemented by at least one of analog circuitry or digital circuitry. In the example of FIG. 1, the mixers 118₁-118_{N} are coupled to the DACs 116₁-116_{N}. For example, the first input of respective mixers is coupled to the output of respective DACs. Also, in the example of FIG. 1, the mixers 118₁-118_{N} are coupled to the local oscillator circuit 106. For example, the second input of respective mixers is coupled to the first output of the local oscillator circuit 106. In the example of FIG. 1, the mixers 118₁-118_{N} are coupled to the phase shifters 120₁-120_{N}. For example, the output of respective mixers is coupled to the input of respective phase shifters.

In the illustrated example of FIG. 1, the local oscillator circuit 106 is implemented by at least one of analog circuitry or digital circuitry. For example, the local oscillator circuit 106 includes a phase locked loop (PLL) oscillator with a voltage-controlled oscillator (VCO). In additional or alternative examples, the local oscillator circuit 106 includes a crystal oscillator. In the example of FIG. 1, the local oscillator circuit 106 is coupled to the mixers 118₁-118_{N}. For example, the first output of the local oscillator circuit 106 is coupled to the second input of respective ones of the mixers 118₁-118_{N}. Also, in the example of FIG. 1, the local oscillator circuit 106 is coupled to the mixers 126₁-126_{M}. For example, the second output of the local oscillator circuit 106 is coupled to the second input of respective ones of the mixers 126₁-126_{M}.

In the illustrated example of FIG. 1, each of the phase shifters 120₁-120_{N} is implemented by at least one of analog or digital circuitry. In the example of FIG. 1, the phase shifters 120₁-20_{N} are coupled to the mixers 118₁-118_{N}. For example, the input of respective phase shifters is coupled to the output of respective mixers. Also, in the example of FIG. 1, the phase shifters 120₁-120_{N} are coupled to the PAs 122₁-122_{N}. For example, the output of respective phase shifters is coupled to the input of respective PAs.

In the illustrated example of FIG. 1, each of the PAs 122₁-122_{N} is implemented by at least one of analog or digital circuitry. In the example of FIG. 1, the PAs 122₁-122_{N} are coupled to the phase shifters 120₁-120_{N}. For example, the input of respective PAs is coupled to the output of respective phase shifters. Also, in the example of FIG. 1, the PAs 122₁-122_{N} are coupled to the transmit antennas 108₁-108_{N}. For example, the output of respective PAs is coupled to respective transmit antennas.

In the illustrated example of FIG. 1, the digital signal generation circuit 102 includes functionality to receive signal parameter values (for example, from the processor circuit 114) for a signal (for example, a data signal to be modulated on a carrier signal, a sequence of chirps in a radar frame, etc.). In some examples, the signal parameters are defined by a system architecture and may include, for example, a transmitter enable parameter for indicating which of the transmitters 104₁-104_{N} to enable, a frequency value for the signal, an ADC sampling time, and a transmitter start time, among others. In the example of FIG. 1, the digital signal generation circuit 102 also includes functionality to generate signals (for example, a data signal to be modulated on a carrier signal, a chirp, etc.) for transmission responsive to the signal parameter values (for example, received from the processor circuit 114). For example, the digital signal generation circuit 102 generates signals for an application in which the RF IC 100 is implemented (for example, a communication application, a radar application, etc.). The frequency of such signal may be between 0 Hz and 18 GHz.

In the illustrated example of FIG. 1, each of the DACs 116₁-116_{N} sample signals generated by the digital signal generation circuit 102. For example, each of the DACs 116₁-116_{N} samples signals generated by the digital signal generation circuit 102 at 64 GSPS. An example DAC that can implement one or more of the DACs 116₁-116_{N} is illustrated and described further herein. In the example of FIG. 1, the local oscillator circuit 106 generates a carrier signal onto which a data signal (for example, generated by the digital signal generation circuit 102) is to be modulated. For example, the local oscillator circuit 106 generates a carrier signal having a frequency between 0 Hz and 18 GHz. In the example of FIG. 1, the mixers 118₁-118_{N} mix the local oscillator (LO) signal with the data signal sampled by each of the DACs 116₁-116_{N}. As such, each of the mixers 118₁-118_{N} generates a modulated signal.

In the illustrated example of FIG. 1, each of the phase shifters 120₁-120_{N} receives a modulated signal provided by respective ones of the mixers 118₁-118_{N} and applies a phase shift to the modulated signal for an application in which the RF IC 100 is utilized. In the example of FIG. 1, each of the phase shifters 122₁-122_{N} amplifies a modulated (and possibly phase shifted) signal received from respective ones of the phase shifters 120₁-120_{N} and provides the amplified signal to respective ones of the transmit antennas 108₁-108_{N}. Also, in the example of FIG. 1, the transmitters 104₁-104_{N} transmit the amplified signals via the transmit antennas 108₁-108_{N}.

In the illustrated example FIG. 1, each of the LNAs 124₁-124_{M} is implemented by at least one of analog or digital circuitry. In the example of FIG. 1, the LNAs 124₁-124_{M} are coupled to the receive antennas 110₁-110_{M}. For example, the input of respective LNAs is coupled to respective ones of the receive antennas 110₁-110_{M}. Also, in the example of FIG. 1, the LNAs 124₁-124_{M} are coupled to the mixers 126₁-126_{M}. For example, the output of respective LNAs is coupled to the first input of respective mixers 126₁-126_{M}.

In the illustrated example of FIG. 1, each of the mixers 126₁-126_{M} is implemented by at least one of analog or digital circuitry. In the example of FIG. 1, the mixers 126₁-126_{M} are coupled to the LNAs 124₁-124_{M}. For example, the first input of respective mixers is coupled to the output of respective LNAs. In the example of FIG. 1, the mixers 126₁-126_{M} are coupled to the local oscillator circuit 106. For example, the second input of respective mixers is coupled to the second output of the local oscillator circuit 106. In the example of FIG. 1, the mixers 126₁-126_{M} are coupled to the ADCs 128₁-128_{M}. For example, the output of respective mixers is coupled to the input of respective ADCs.

In the illustrated example of FIG. 1, each of the ADCs 128₁-128_{M} is implemented by at least one of analog or digital circuitry. In the example of FIG. 1, the ADCs 128₁-128_{M} are coupled to the mixers 126₁-126_{M}. For example, the input of respective ADCs is coupled to the output of respective mixers. Also, in the example of FIG. 1, the ADCs 128₁-128_{M} are coupled to the processor circuit 114. For example, the output of respective ADCs is coupled to the input of the processor circuit 114.

In the illustrated example of FIG. 1, the processor circuit 114 is implemented by at least one of analog or digital circuitry. For example, the processor circuit 114 may be implemented by a DSP, a microcontroller, an FFT engine, a combined DSP and microcontroller processor, an FPGA, or an application specific integrated circuit (ASIC). In the example of FIG. 1, the input of the processor circuit 114 is coupled to output of respective ones of the ADCs 128₁-128_{M}. In some examples, the processor circuit 114 is coupled to the digital signal generation circuit 102.

In the illustrated example of FIG. 1, each of the receive antennas 110₁-110_{M} receives signals from an environment in a field of view of the RF IC 100. For example, each of the receive antennas 110₁-110_{M} receives cell signals from the environment. In additional or alternative examples, each of the receive antennas 110₁-110_{M} receive radar frames from the environment. In the example of FIG. 1, each of the LNAs 124₁-124_{M} amplifies the signals and forwards the amplified received signals to the mixers 126₁-126_{M}. In the example of FIG. 1, each of the mixers 126₁-126_{M} mixes the amplified received signals with the LO signal provided by the local oscillator circuit 106 to produce IF received signals. Also, in the example of FIG. 1, each of the ADCs 128₁-128_{M} converts the IF received signals from the analog domain to the digital domain.

In some examples, the RF IC 100 includes digital front end (DFE) circuitry between the ADCs 128₁-128_{M} and the processor circuit 114. For example, the DFE circuitry receives IF signals from the receivers 112₁-112_{M} and performs decimation filtering or other processing operations on the digital IF signals, for example, to reduce the data transfer rate of the digital IF signals. Also or alternatively, the DFE circuitry performs other operations on the digital IF signals such as direct current (DC) offset removal or compensation (for example, digital compensation) of non-idealities in the receivers 112₁-112_{M} such as inter-receiver gain imbalance non-ideality, inter-receiver phase imbalance non-ideality, and the like.

In the illustrated example of FIG. 1, the processor circuit 114 is to perform at least a portion of signal processing on the digital signals resulting from a received analog signal. In some examples, the processor circuit 114 is to transmit the results of signal processing. For example, the processor circuit 114 transmits the results of signal processing to a processing unit. In some examples, the processor circuit 114 interfaces with another device via a high-speed interface or a serial peripheral interface (SPI). In the example of FIG. 1, the processor circuit 114 performs an FFT on each received signal. In some examples, the processor circuit 114 receives control information (for example, timing of signals, power level, triggering of monitoring functions, etc.) via an SPI. For example, responsive to the control information, the processor circuit 114 provides data parameters or provides control signals to the digital signal generation circuit 102.

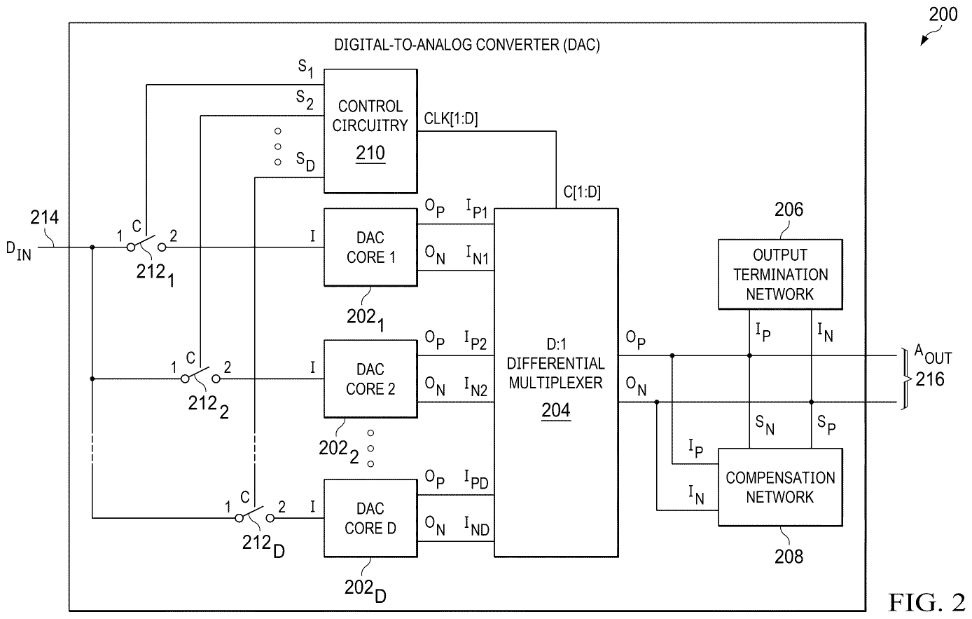

FIG. 2 is a block diagram of an example DAC 200 that can implement one or more of the DACs 116₁-116_{N} of FIG. 1. In the example of FIG. 2, the DAC 200 includes example DAC cores 202₁-202_{D}, an example differential multiplexer 204, an example output termination network 206, an example compensation network 208, example control circuitry 210, and example sampling switches 212₁-212_{D}. In the example of FIG. 2, each of the DAC cores 202₁-202_{D} has an input, a positive output, and a negative output. Also, in the example of FIG. 2, the differential multiplexer 204 selects between D differential inputs responsive to D control signals to generate one differential output. As such, the differential multiplexer 204 has D sets of positive inputs and negative inputs, D control terminals, a positive output, and a negative output.

In the illustrated example of FIG. 2, the output termination network 206 has a positive input and a negative input. In the example of FIG. 2, the compensation network 208 has a positive input, a negative input, a positive supply terminal, and a negative supply terminal. Also, in the example of FIG. 2, the control circuitry 210 has D clock terminals and D sample terminals. In the example of FIG. 2, each of the sampling switches 212₁-212_{D} has a control terminal (a gate terminal), a first terminal (a drain terminal), and a second terminal (a source terminal).

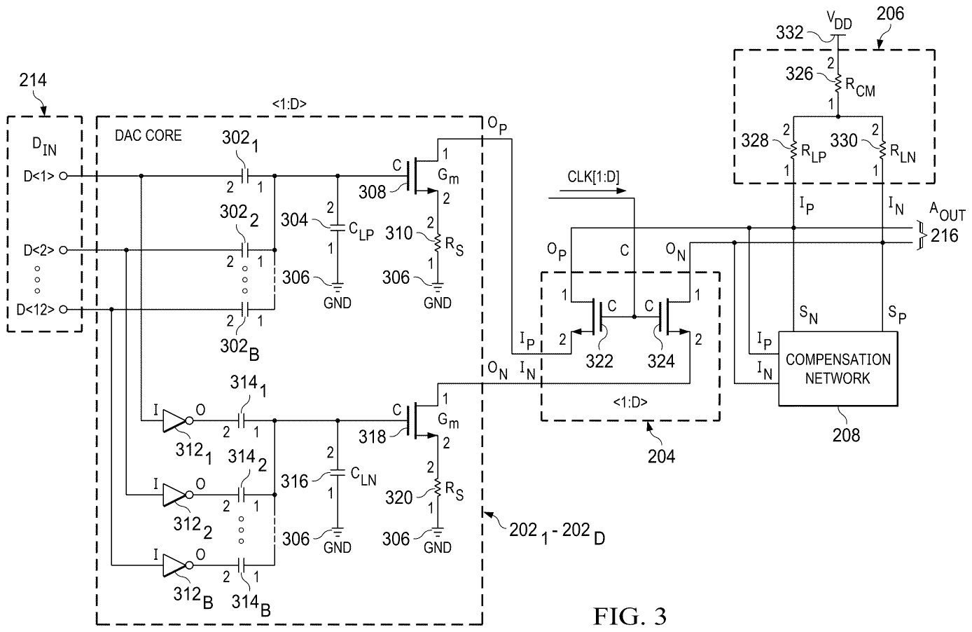

In the illustrated example of FIG. 2, each of the DAC cores 202₁-202_{D} is implemented by at least one analog circuitry or digital circuitry. For example, each of the DAC cores 202₁-202_{D} includes two cells where each cell includes B capacitors to receive an example digital signal 214 (D_{IN}) having B-bits (or the inverse of the digital signal 214), a capacitor to sum the value of the B-bits, and a source-degenerated transistor to set an output current from the cell. In the example of FIG. 2, the digital signal 214 is a 12-bit signal (the number of bits is 12, B is 12, etc.). An example implementation of each of the DAC cores 202₁-202_{D} is illustrated and described in connection with FIG. 3.

In the illustrated example of FIG. 2, the input of each of the DAC cores 202₁-202_{D} is coupled second terminal of respective ones of the sampling switches 212₁-212_{D}. For example, the input of a first example DAC core 202₁ is coupled to the second terminal of a first example sampling switch 212₁. In the example of FIG. 2, the input of a second example DAC core 202₂ is coupled to the second terminal of a second example sampling switch 212₂. Also, in the example of FIG. 2, the input of a Dth example DAC core 202_{D} is coupled to the second terminal of a Dth example sampling switch 212_{D}.

In the illustrated example of FIG. 2, the positive output and the negative output of each of the DAC cores 202₁-202_{D} are coupled to a positive input and a negative input of the differential multiplexer 204, respectively. For example, the positive output and the negative output of the DAC core 202₁ are coupled to a first positive input and a first negative input of the differential multiplexer 204, respectively. In the example of FIG. 2, the positive output and the negative output of the DAC core 202₂ are coupled to a second positive input and a second negative input of the differential multiplexer 204, respectively. Also, in the example of FIG. 2, the positive output and the negative output of the DAC core 202_{D} are coupled to a Dth positive input and a Dth negative input of the differential multiplexer 204, respectively.

In the illustrated example of FIG. 2, the differential multiplexer 204 is implemented by at least one of analog circuitry or digital circuitry. For example, the differential multiplexer 204 includes D multiplexer cores where each multiplexer core includes two transistors with control terminals (gate terminals) coupled to the same clock terminal of the control circuitry 210. Responsive to the values at the clock terminals of the control circuitry 210, the differential multiplexer 204 provides an example analog signal 216 (A_{OUT}) measured between the positive output and negative output of the differential multiplexer 204. An example implementation of a multiplexer cell of the differential multiplexer 204 is illustrated and described in connection with FIG. 3.

In the illustrated example of FIG. 2, respective ones of the D sets of positive inputs and negative inputs of the differential multiplexer 204 are coupled to the positive outputs and negative outputs of respective ones of the DAC cores 202₁-202_{D}. For example, the first positive input and the first negative input of the differential multiplexer 204 are coupled to the positive input and the negative input of the DAC core 202₁, respectively. In the example of FIG. 2, the second positive input and the second negative input of the differential multiplexer 204 are coupled to the positive input and the negative input of the DAC core 202₂, respectively. Also, in the example of FIG. 2, the Dth positive input and the Dth negative input of the differential multiplexer 204 are coupled to the positive input and the negative input of the DAC core 202_{D}, respectively.

In the illustrated example of FIG. 2, the D control terminals of the differential multiplexer 204 are coupled to the D clock terminals of the control circuitry 210, respectively. In the example of FIG. 2, the positive output of the differential multiplexer 204 is coupled to the positive input of the output termination network 206, the positive input of the compensation network 208, and the negative supply terminal of the compensation network 208. Also, in the example of FIG. 2, the negative output of the differential multiplexer 204 is coupled to the negative input of the output termination network 206, the negative input of the compensation network 208, and the positive supply terminal of the compensation network 208.

In the illustrated example of FIG. 2, the output termination network 206 is implemented by at least one of analog circuitry or digital circuitry. For example, the output termination network 206 is implemented by one or more resistors. An example implementation of the output termination network 206 is illustrated and described in connection with FIG. 3. In the example of FIG. 2, the positive input of the output termination network 206 is coupled to the positive output of the differential multiplexer 204. Also, in the example of FIG. 2, the negative input of the output termination network 206 is coupled to the negative output of the differential multiplexer 204.

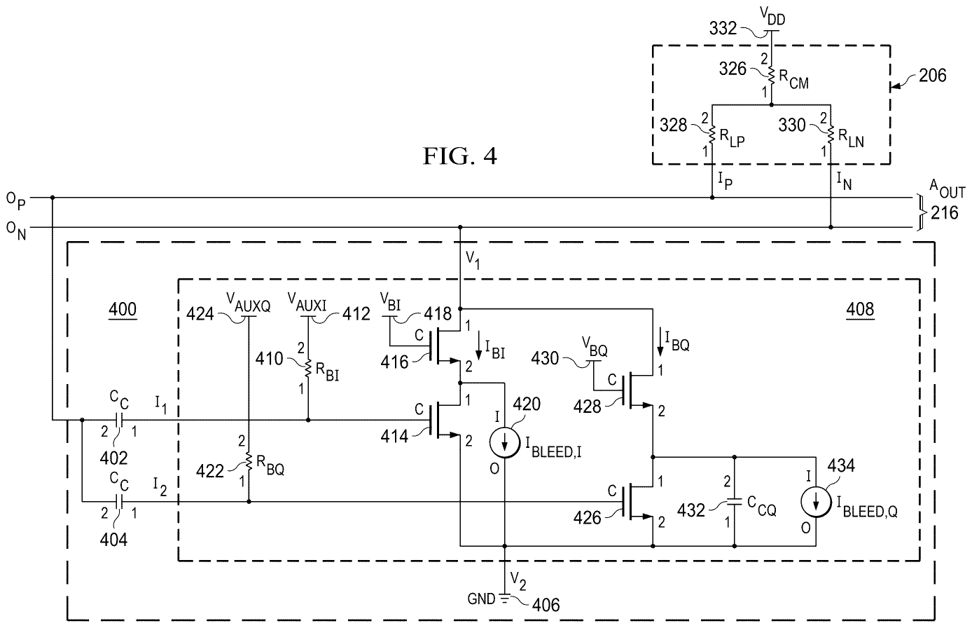

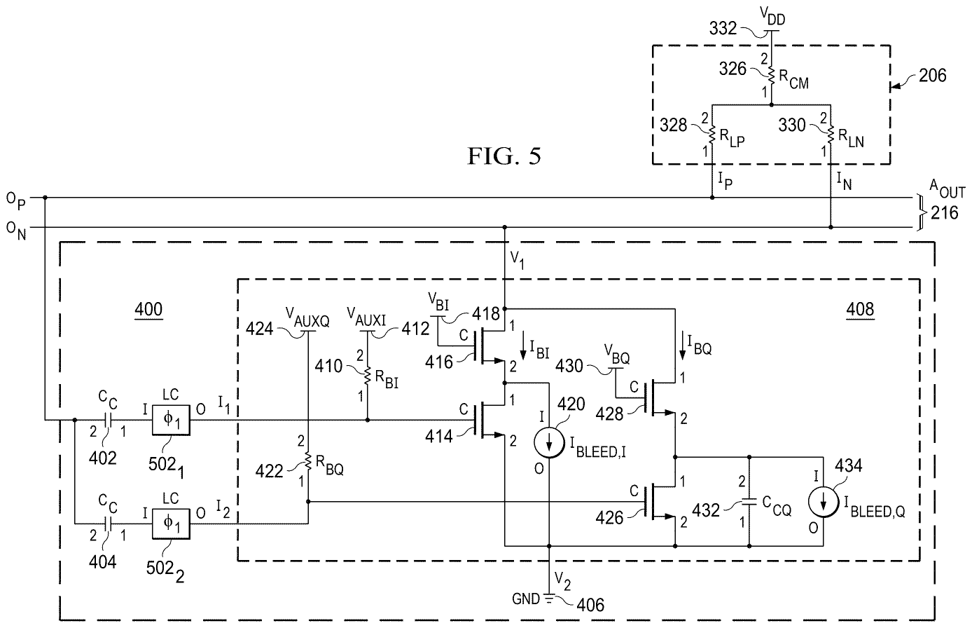

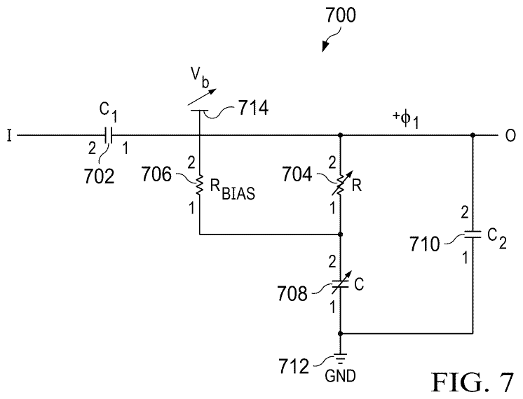

In the illustrated example of FIG. 2, the compensation network 208 is implemented by at least one of analog circuitry or digital circuitry. Example implementations of compensation circuits that can implement the compensation network 208 of FIG. 2 are illustrated and described in connection with FIGS. 4 and 5. Also, an example implementation of the compensation network 208 is illustrated and described in connection with FIG. 7. In the example of FIG. 2, the positive input of the compensation network 208 is coupled to the positive output of the differential multiplexer 204. Also, in the example of FIG. 2, the negative input of the compensation network 208 is coupled to the negative output of the differential multiplexer 204. In the example of FIG. 2, the positive supply terminal of the compensation network 208 is coupled to the negative output of the differential multiplexer 204. Also, in the example of FIG. 2, the negative supply terminal of the compensation network 208 is coupled to the positive output of the differential multiplexer 204.

In the illustrated example of FIG. 2, the control circuitry 210 is implemented by at least one of analog circuitry or digital circuitry. In the example of FIG. 2, the D clock terminals of the control circuitry 210 are coupled to the D control terminals of the differential multiplexer 204, respectively. Also, in the example of FIG. 2, the D sample terminals of the control circuitry 210 are coupled to the control terminals of the sampling switches 212₁-212_{D}, respectively. For example, a first sample terminal of the control circuitry 210 is coupled to the control terminal of the sampling switch 212₁, a second sample terminal of the control circuitry 210 is coupled to the control terminal of the sampling switch 212₂, and a Dth sample terminal of the control circuitry 210 is coupled to the control terminal of the sampling switch 212_{D}.

In the illustrated example of FIG. 2, each of the sampling switches 212₁-212_{D} is implemented by at least one of analog circuitry or digital circuitry. While in the example of FIG. 2 each of the sampling switches 212₁-212_{D} is illustrated as a single switch, in reality each of the sampling switches 212₁-212_{D} may be implemented as one or more switches (for example, transistors) corresponding to the number of bits of the digital signal 214. For example, in the example of FIG. 2, the digital signal 214 is a 12-bit signal and as such each of the sampling switches 212₁-212_{D} is implemented by twelve switches. In the example of FIG. 2, the control terminals of respective ones of the sampling switches 212₁-212_{D} are coupled to the D sample terminals of the control circuitry 210, respectively. For example, the control terminal of the sampling switch 212₁ is coupled to the first sample terminal of the control circuitry 210, the control terminal of the sampling switch 212₂ is coupled to the second sample terminal of the control circuitry 210, and the control terminal of the sampling switch 212_{D} is coupled to the Dth sample terminal of the control circuitry 210.

In the illustrated example of FIG. 2, the first terminals of respective ones of the sampling switches 212₁-212_{D} are coupled together and receive the digital signal 214. In the example of FIG. 2, the second terminals of respective ones of the sampling switches 212₁-212_{D} are coupled to the inputs of respective ones of the DAC cores 202₁-202_{D}. For example, the second terminal of the sampling switch 212₁ is coupled to the input of the DAC core 202₁. In the example of FIG. 2, the second terminal of the sampling switch 212₂ is coupled to the input of the DAC core 202₂. Also, in the example of FIG. 2, the second terminal of the sampling switch 212_{D} is coupled to the input of the DAC core 202_{D}.

In the illustrated example of FIG. 2, the DAC 200 samples the digital signal 214 at 64 GSPS. To implement 64 GSPS sampling, the DAC 200 includes eight of the DAC cores 202₁-202_{D} (the number of the DAC cores 202₁-202_{D} is eight, D is 8, etc.) where the DAC cores 202₁-202_{D} are interleaved and each of the DAC cores 202₁-202_{D} samples the digital signal 214 at 8 GSPS. To interleave sampling by the DAC cores 202₁-202_{D}, the DAC 200 implements Equation 1 below.

$${\sum }_{∀ n} x ( n * {T}_{s} ) = {\sum }_{∀ n} x ( t ) * \partial ( t - n * {T}_{s} ) = {f}_{s} * {\sum }_{m = - ∞}^{∞} x ( f - m * {f}_{s} ) \qquad Equation 1$$

In Equation 1, Σ_{∀n}x(n*T_{S}) represents the sampled version of the digital signal 214 where x(t) represents the digital signal 214 and Tₛ represents the sampling period. Also, in Equation 1, Σ_{∀n}x(t)*∂(t−n*T_{S}) represents sampling of the digital signal 214 (x(t)) in terms of the Dirac delta function ∂(t−n*T_{S}) where the digital signal 214 (x(t)) is sampled at discrete instants of t=nTₛ. In Equation 1,

$${f}_{s} * {\sum }_{m = - ∞}^{∞} x ( f - m * {f}_{s} )$$

represents sampling of the digital signal 214 (x(t)) as the periodic summation of the digital signal 214 (x(t)) in the frequency domain where m corresponds to periodic repetition of the signal x(f) at integer multiples of the sampling frequency fₛ.

To implement Equation 1, the control circuitry 210 drives the sampling switches 212₁-212_{D} in a sequential manner. For example, the control circuitry 210 drives the sampling switch 212₁ according to the period n*Tₛ, the control circuitry 210 drives the sampling switch 212₂ according to the period (n+1)*Tₛ, and so on, until the sampling switch 212_{D} which the control circuitry 210 drives according to the period (n+[D−1])*Tₛ. Also, to implement Equation 1, the control circuitry 210 drives the D control terminals of the differential multiplexer 204 with D clock signals having a frequency fₛ.

According to the sampling set forth in Equation 1, the frequency domain of the analog signal 216 measured between the positive output and the negative output of the differential multiplexer 204 may include a number of frequency spurs at n*fₛ±fᵢₙ. To cancel frequency spurs in the analog signal 216, the DAC 200 includes the compensation network 208. As described herein, the compensation network 208 senses the analog signal 216 at the output of the differential multiplexer 204 and feeds the analog signal 216 back through the compensation network 208 with opposite polarity. For example, the positive output of the differential multiplexer 204 is coupled to the negative supply terminal of the compensation network 208 and the negative output of the differential multiplexer 204 is coupled to the positive supply terminal of the compensation network 208 as described above.

By sensing at the output of the differential multiplexer 204, interleaving frequency spurs and corresponding IMD₃ components are inherently removed from the analog signal 216. For example, at the output of the differential multiplexer 204, the interleaving frequency spurs and corresponding IMD₃ components have been cancelled out in the analog signal 216 as a result of the interleaving process. Also, implementing the compensation network 208 at the output of the differential multiplexer 204 is area efficient. For example, as the compensation network 208 is common to all of the DAC cores 212₁-212_{D} (for example, the compensation network 208 is implemented once), the area on a chip consumed by the compensation network 208 is 87.5% smaller than the area of a chip consumed by other techniques (for example, where an auxiliary pair of gₘ transistor and associated circuitry is implemented in each DAC core).

Also, implementing the compensation network 208 at the output of the differential multiplexer 204 provides better intrinsic linearity for the DAC 200 than other techniques (for example, where an auxiliary pair of gₘ transistor and associated circuitry is implemented in each DAC core). For example, the DAC 200 has a SFDR of greater than 55 dBc across the input frequency range of the DAC 200. By implementing the compensation network 208 at the output of the differential multiplexer 204, the DAC 200 also reduces layout complexity (for example, complex routing and placement of components) compared to other techniques (for example, where an auxiliary pair of gₘ transistor and associated circuitry is implemented in each DAC core). As such, the DAC 200 can sample at 64 GSPS across a bandwidth of 18 GHz and supports a variety of application described above.

FIG. 3 is schematic diagram of example implementations of the DAC cores 202₁-202_{D}, the differential multiplexer 204, and the output termination network 206 of FIG. 2. In the example of FIG. 3, each of the DAC cores 202₁-202_{D} includes first example coupling capacitors 302₁-302_{B}, a first example sampling capacitor 304, an example ground terminal 306, a first example transconductance transistor 308, a first example resistor 310, example inverters 312₁-312_{B}, second example coupling capacitors 314₁-314_{B}, a second example sampling capacitor 316, a second example transconductance transistor 318, and a second example resistor 320. Also, in the example of FIG. 3, the differential multiplexer 204 includes D cells where each cell includes a first example transistor 322 and a second example transistor 324. In the example of FIG. 3, the output termination network 206 includes a third example resistor 326, a fourth example resistor 328, and a fifth example resistor 330.

In the illustrated example of FIG. 3, each of the coupling capacitors 302₁-302^{B}, the sampling capacitor 304, the resistor 310, the coupling capacitors 314₁-314_{B}, the sampling capacitor 316, the resistor 320, the resistor 326, the resistor 328, and the resistor 330 has a first terminal and a second terminal. In the example of FIG. 3, each of the transconductance transistor 308, the transconductance transistor 318, the transistor 322, and the transistor 324 has a control terminal (a gate terminal), a first terminal (a drain terminal), and a second terminal (a source terminal). Also, in the example of FIG. 3, each of the inverters 312₁-312_{B} has an input and an output.

In the illustrated example of FIG. 3, the coupling capacitors 302₁-302_{B} include B capacitors corresponding to the number of bits of the digital signal 214. As described above, the digital signal 214 is a 12-bit signal. As such, the coupling capacitors 302₁-302^{B} include 12 capacitors. In the example of FIG. 3, the first terminal of each of the coupling capacitors 302₁-302^{B} is coupled to the second terminal of the sampling capacitor 304 and the second terminal of each of the coupling capacitors 302₁-302_{B} receives the digital signal 214. Also, in the example of FIG. 3, the sampling capacitor 304 has a capacitance of C_{LP}. In the example of FIG. 3, the first terminal of the sampling capacitor 304 is coupled to the ground terminal 306 and the second terminal of the sampling capacitor 304 is coupled to the first terminal of each of the coupling capacitors 302₁-302_{B}.

In the illustrated example of FIG. 3, the transconductance transistor 308 is an N-type channel (N-channel) field-effect transistor (FET) such as an N-channel metal-oxide semiconductor (MOS) FET (MOSFET). In the example of FIG. 3, the control terminal of the transconductance transistor 308 is coupled to the first terminal of each of the coupling capacitors 302₁-302^{B}. Also, in the example of FIG. 3, the first terminal of the transconductance transistor 308 is coupled to the second terminal of the transistor 322 and is to operate as the positive output of the respective ones of the DAC cores 202₁-202_{D}. In the example of FIG. 3, the second terminal of the transconductance transistor 308 is coupled to the second terminal of the resistor 310. Also, in the example of FIG. 3, the resistor 310 has a resistance of R_{S}. In the example of FIG. 3, the first terminal of the resistor 310 is coupled to the ground terminal 306 and the second terminal of the resistor 310 is coupled to the second terminal of the transconductance transistor 308.

In the illustrated example of FIG. 3, each of the inverters 312₁-312_{B} is implemented by digital logic circuitry (for example, a NOT gate). In the example of FIG. 3, the output of each of the inverters 312₁-312_{B} is coupled to the second terminal of respective ones of the coupling capacitors 314₁-314_{B}. For example, the output of a first example inverter 312₁ is coupled to the second terminal of a first example coupling capacitor 314₁, the output of a second example inverter 312₂ is coupled to the second terminal of a second example coupling capacitor 314₂, and the output of a Bth example inverter 312_{B} is coupled to the second terminal of a Bth example coupling capacitor 314_{B}. Also, in the example of FIG. 3, the input of each of the inverters 312₁-312_{B} is coupled to the second terminal of respective ones of the coupling capacitors 302₁-302_{B}. For example, the input of the inverter 312₁ is coupled to the second terminal of a first example coupling capacitor 302₁, the input of the inverter 312₂ is coupled to the second terminal of a second example coupling capacitor 302₂, and the input of the inverter 312_{B} is coupled to the second terminal of a Bth example coupling capacitor 302_{B}. In the example of FIG. 3, the second terminals of the coupling capacitors 302₁-302_{B} and the inputs of the inverters 312₁-312_{B} are to operate as the inputs of the respective ones of the DAC cores 202₁-202_{D}.

In the illustrated example of FIG. 3, the coupling capacitors 314₁-314_{B} include B capacitors corresponding to the number of bits of the digital signal 214. As described above, the digital signal 214 is a 12-bit signal. As such, the coupling capacitors 314₁-314_{B} include 12 capacitors. In the example of FIG. 3, the first terminal of each of the coupling capacitors 314₁-314_{B} is coupled to the second terminal of the sampling capacitor 316. Also, in the example of FIG. 3, the second terminal of each of the coupling capacitors 314₁-314_{B} is coupled to the output of respective ones of the inverters 312₁-312_{B}. For example, the second terminal of the coupling capacitor 314₁ is coupled to the output of the inverter 312₁, the second terminal of the coupling capacitor 314₂ is coupled to the output of the inverter 312₂, and the second terminal of the coupling capacitor 314_{B} is coupled to the output of the inverter 312_{B}. In the example of FIG. 3, the sampling capacitor 316 has a capacitance of C_{LN}. Also, in the example of FIG. 3, the first terminal of the sampling capacitor 316 is coupled to the ground terminal 306 and the second terminal of the sampling capacitor 316 is coupled to the first terminal of each of the coupling capacitors 314₁-314_{B}.

In the illustrated example of FIG. 3, the transconductance transistor 318 is an N-channel FET such as an N-channel MOS (NMOS) FET. In the example of FIG. 3, the control terminal of the transconductance transistor 318 is coupled to the first terminal of each of the coupling capacitors 314₁-314_{B}. Also, in the example of FIG. 3, the first terminal of the transconductance transistor 318 is coupled to the second terminal of the transistor 324 and is to operate as the negative output of the respective ones of the DAC cores 202₁-202_{D}. In the example of FIG. 3, the second terminal of the transconductance transistor 318 is coupled to the second terminal of the resistor 320. Also, in the example of FIG. 3, the resistor 320 has a resistance of R_{S}. In the example of FIG. 3, the first terminal of the resistor 320 is coupled to the ground terminal 306 and the second terminal of the resistor 320 is coupled to the second terminal of the transconductance transistor 318.

As described above, in the example of FIG. 3, the differential multiplexer 204 includes D cells where each cell includes a positive input, a negative input, a positive output, a negative output, and a control terminal. For example, the positive input and the negative input of respective cells are to operate as the respective sets of positive inputs and negative inputs of the differential multiplexer 204. Also, for example, the positive output of respective cells is to operate as the positive output of the differential multiplexer 204 and the negative output of respective cells are to operate as the negative output of the differential multiplexer 204. The control terminal of respective cells is to operate as respective control terminals of the differential multiplexer 204.

In the illustrated example of FIG. 3, each of the D cells of the differential multiplexer 204 includes an instance of the transistor 322 and an instance of the transistor 324. For example, the D cells correspond to the D clock signals provided by the control circuitry 210. In the example of FIG. 3, the transistor 322 and the transistor 324 are cascode transistors. Also, in the example of FIG. 3, the transistor 322 is an N-channel FET such as an NMOS FET. In the example of FIG. 3, the control terminal of the transistor 322 is coupled to the control terminal of the transistor 324 and the control terminal of the transistor 322 receives one of the D clock signals from the control circuitry 210.

In the illustrated example of FIG. 3, the first terminal of the transistor 322 is coupled to the first terminal of the of the resistor 328, the positive input of the compensation network 208, and the negative supply terminal of the compensation network 208. For example, the first terminal of the transistor 322 is to operate as the positive output of the respective cells of the differential multiplexer 204. In the example of FIG. 3, the second terminal of the transistor 322 is coupled to the first terminal of the transconductance transistor 308. For example, the second terminal of the transistor 322 is to operate as the positive input of the respective cells of the differential multiplexer 204.

In the illustrated example of FIG. 3, the transistor 324 is an N-channel FET such as an NMOS FET. In the example of FIG. 3, the control terminal of the transistor 324 is coupled to the control terminal of the transistor 322 and the control terminal of the transistor 324 receives one of the D clock signals from the control circuitry 210. For example, the control terminal of the transistor 322 and the control terminal of the transistor 324 are to operate as the control terminal of the respective cells of the differential multiplexer 204.

In the illustrated example of FIG. 3, the first terminal of the transistor 324 is coupled to the first terminal of the resistor 330, the negative input of the compensation network 208, and the positive supply terminal of the compensation network 208. For example, the first terminal of the transistor 324 is to operate as the negative output of the respective cells of the differential multiplexer 204. In the example of FIG. 3, the second terminal of the transistor 324 is coupled to the first terminal of the transconductance transistor 318. For example, the second terminal of the transistor 324 is to operate as the negative input of the respective cells of the differential multiplexer 204.

In the illustrated example of FIG. 3, the resistor 326 has a resistance of R_{CM}. In the example of FIG. 3, the first terminal of the resistor 326 is coupled to the second terminal of the resistor 328 and the second terminal of the resistor 330. Also, in the example of FIG. 3, the second terminal of the resistor 326 is coupled to an example supply terminal 332. For example, the supply terminal 332 is at a voltage of V_{DD}.

In the illustrated example of FIG. 3, the resistor 328 has a resistance of R_{LP}. In the example of FIG. 3, the first terminal of the resistor 328 is coupled to the first terminal of the transistor 322, the positive input of the compensation network 208, and the negative supply terminal of the compensation network 208. For example, the first terminal of the resistor 328 is to operate as the positive input of the output termination network 206. In the example of FIG. 3, the second terminal of the resistor 328 is coupled to the first terminal of the resistor 326 and the second terminal of the resistor 330.

In the illustrated example of FIG. 3, the resistor 330 has a resistance of R_{LN}. In the example of FIG. 3, the first terminal of the resistor 330 is coupled to the first terminal of the transistor 324, the negative input of the compensation network 208, and the positive supply terminal of the compensation network 208. For example, the first terminal of the resistor 330 is to operate as the negative input of the output termination network 206. In the example of FIG. 3, the second terminal of the resistor 330 is coupled to the first terminal of the resistor 326 and the second terminal of the resistor 328.

In the illustrated examples of FIG. 3, the transistors 308, 318, 322, 324 are N-channel MOSFETs. Alternatively, the transistors 308, 318, 322, 324 may be N-channel FETs, N-channel insulated-gate bipolar transistors (IGBTs), N-channel junction field effect transistors (JFETs), N-type, P-type, N-type (NPN) bipolar junction transistors (BJTs) or, with slight modifications, P-type equivalent devices. The transistors 308, 318, 322, 324 may be depletion mode devices, drain-extended devices, enhancement mode devices, natural transistors or other type of device structure transistors. Furthermore, the transistors 308, 318, 322, 324 may be implemented in/over a silicon (Si) substrate, a silicon carbide (SiC) substrate, a gallium nitride (GaN) substrate, or a gallium arsenide (GaAs) substrate.

As described above, the DAC cores 202₁-202_{D} includes eight DAC cores where each of the DAC cores 202₁-202_{D} samples the digital signal 214. For example, the digital signal 214 is a 12-bit signal. As such, each of the coupling capacitors 302₁-302_{B} receives one of the bits of the digital signal 214 and the sampling capacitor 304 sums the values of the 12 bits to set a voltage at the control terminal of the transconductance transistor 308 which sets an analog current through the transconductance transistor 308. Likewise, each of the coupling capacitors 314₁-314_{B} receives one of the bits of the inverted version of the digital signal 214 and the sampling capacitor 316 sums the values of the 12 bits to set a voltage at the control terminal of the transconductance transistor 318 which sets an analog current through the transconductance transistor 318. As such, each of the DAC cores 202₁-202_{D} coverts the digital signal 214 to an analog signal. By sampling the digital signal 214 via the coupling capacitors 302₁-302^{B}, the sampling capacitor 304, the coupling capacitors 314₁-314_{B}, and the sampling capacitor 316, each of the DAC cores 202₁-202_{D} supports sampling across a high bandwidth (for example, 0 Hz to 18 GHz).

Depending on the D clock signals from the control circuitry 210, the differential multiplexer 204 determines which of the DAC cores 202₁-202_{D} provides the analog signal 216 at a given instance of time. For example, the control circuitry 210 generates the D clock signals as eight non-overlapping pulses with a frequency of 8 GHz where each pulse has a width of 15.625 picoseconds (ps). As such, the cells of the differential multiplexer 204 (for example, implemented by respective instances of the transistor 322 and the transistor 324) facilitate interleaving.

As described herein, transconductance transistors can introduce non-linearities that dominate the overall non-linearity in an analog signal provided by an interleaved DAC. Advantageously, by implementing the compensation network 208 at the output of the differential multiplexer 204, the compensation network 208 cancels out non-linearities that may be introduced by any of the transconductance transistor 308 or the transconductance transistor 318 of any of the DAC cores 202₁-202_{D}. Accordingly, the compensation network 208 reduces the non-linearity of the analog signal 216 (for example, improves SFDR) across the 18 GHz bandwidth of the DAC 200.

FIG. 4 is a schematic diagram of an example compensation circuit 400 with one input and one supply terminal that can implement the compensation network 208 of FIG. 2. In the example of FIG. 4, the compensation network 400 includes a first example capacitor 402, a second example capacitor 404, an example ground terminal 406, and an example cancellation circuit 408. In the example of FIG. 4, the cancellation circuit 408 includes a first example resistor 410, a first example in-phase biasing terminal 412, a first example transistor 414, a second example transistor 416, a second example in-phase biasing terminal 418, a first example current source circuit 420, a second example resistor 422, a first example quadrature biasing terminal 424, a third example transistor 426, a fourth example transistor 428, a second example quadrature biasing terminal 430, a third example capacitor 432, and a second example current source circuit 434.

In the illustrated example of FIG. 4, each of the capacitor 402, the capacitor 404, the resistor 410, the resistor 422, and the capacitor 432 has a first terminal and a second terminal. In the example of FIG. 4, each of the current source circuit 420 and the current source circuit 434 has an input and an output. Also, in the example of FIG. 4, each of the transistor 414, the transistor 416, the transistor 426, and the transistor 428 has a control terminal (a gate terminal), a first terminal (a drain terminal), and a second terminal (a source terminal). In the example of FIG. 4, the cancellation circuit 408 has a first input, a second input, a first voltage terminal, and a second voltage terminal.

In the illustrated example of FIG. 4, the capacitor 402 has a capacitance of Cc. In the example of FIG. 4, the second terminal of the capacitor 402 is coupled to the positive output of the differential multiplexer 204 and the first terminal of the capacitor 402 is coupled to the control terminal of the transistor 414. In the example of FIG. 4, the capacitor 404 has a capacitance of Cc. Also, in the example of FIG. 4, the second terminal of the capacitor 404 is coupled to the positive output of the differential multiplexer 204 and the first terminal of the capacitor 404 is coupled to the control terminal of the transistor 426. As such, the second terminal of the capacitor 402 and the second terminal of the capacitor 404 are to operate as the input of the compensation network 400.

In the illustrated example of FIG. 4, the first input of the cancellation circuit 408 is coupled to the first terminal of the capacitor 402 and the second input of the cancellation circuit 408 is coupled to the first terminal of the capacitor 404. In the example of FIG. 4, the first voltage terminal of the cancellation circuit 408 is coupled to the negative output of the differential multiplexer 204 and the second voltage terminal of the cancellation circuit 408 is coupled to the ground terminal 406. In the example of FIG. 4, the resistor 410 has a resistance of R_{BI}. In the example of FIG. 4, the second terminal of the resistor 410 is coupled to the in-phase biasing terminal 412. For example, the in-phase biasing terminal 412 is at a voltage of V_{AUXI}. In the example of FIG. 4, the first terminal of the resistor 410 is coupled to the control terminal of the transistor 414.

In the illustrated example of FIG. 4, the transistor 414 is an N-channel FET such as an NMOS FET. In the example of FIG. 4, the control terminal of the transistor 414 is coupled to the first terminal of the capacitor 402 and the first terminal of the resistor 410. As such, the control terminal of the transistor 414 is to operate as the first input of the cancellation circuit 408. In the example of FIG. 4, the first terminal of the transistor 414 is coupled to the second terminal of the transistor 416. Also, in the example of FIG. 4, the second terminal of the transistor 414 is coupled to the ground terminal 406.

In the illustrated example of FIG. 4, the transistor 416 is an N-channel FET such as an NMOS FET. In the example of FIG. 4, the control terminal of the transistor 416 is coupled to the in-phase biasing terminal 418. For example, the in-phase biasing terminal 418 is at a voltage of V_{BI}. In the example of FIG. 4, the first terminal of the transistor 416 is coupled to the negative output of the differential multiplexer 204. As such, the first terminal of the transistor 416 is to operate as the first voltage terminal of the cancellation circuit 408. In the example of FIG. 4, the second terminal of the transistor 416 is coupled to the first terminal of the transistor 414. Also, in the example of FIG. 4, the current source circuit 420 provides a current of I_{BLEED, I}. In the example of FIG. 4, the input of the current source circuit 420 is coupled to the second terminal of the transistor 416 and the output of the current source circuit 420 is coupled to the ground terminal 406.

In the illustrated example of FIG. 4, the resistor 422 has a resistance of R_{BQ}. In the example of FIG. 4, the second terminal of the resistor 422 is coupled to the quadrature biasing terminal 424. For example, the quadrature biasing terminal 424 is at a voltage of V_{AUXQ}. In the example of FIG. 4, the first terminal of the resistor 422 is coupled to the control terminal of the transistor 426.

In the illustrated example of FIG. 4, the transistor 426 is an N-channel FET such as an NMOS FET. In the example of FIG. 4, the control terminal of the transistor 426 is coupled to the first terminal of the capacitor 404 and the first terminal of the resistor 422. As such, the control terminal of the transistor 426 is to operate as the second input of the cancellation circuit 408. In the example of FIG. 4, the first terminal of the transistor 426 is coupled to the second terminal of the transistor 428. Also, in the example of FIG. 4, the second terminal of the transistor 426 is coupled to the ground terminal 406.

In the illustrated example of FIG. 4, the transistor 428 is an N-channel FET such as an NMOS FET. In the example of FIG. 4, the control terminal of the transistor 428 is coupled to the quadrature biasing terminal 430. For example, the quadrature biasing terminal 430 is at a voltage of V_{BQ}. In the example of FIG. 4, the first terminal of the transistor 428 is coupled to the first terminal of the transistor 416. Also, in the example of FIG. 4, the second terminal of the transistor 428 is coupled to the first terminal of the transistor 426.

In the illustrated example of FIG. 4, the capacitor 432 has a capacitance of C_{CQ}. In the example of FIG. 4, the second terminal of the capacitor 432 is coupled to the second terminal of the transistor 428. Also, in the example of FIG. 4, the first terminal of the capacitor 432 is coupled to the ground terminal 406. In the example of FIG. 4, the current source circuit 434 provides a current of I_{BLEED, Q}. In the example of FIG. 4, the input of the current source circuit 434 is coupled to the second terminal of the transistor 428 and the output of the current source circuit 434 is coupled to the ground terminal 406. As such, the second terminal of the transistor 414, the output of the current source circuit 420, the second terminal of the transistor 426, the first terminal of the capacitor 432, and the output of the current source circuit 434 are to operate as the second voltage terminal of the cancellation circuit 408.

As described above, transconductance transistors of DAC cores can introduce non-linearities, such as IMD₃ components and HD₃ components, that dominate the overall non-linearity in an analog signal provided by an interleaved DAC. To compensate for IMD₃ and HD₃ non-linearity components, the cancellation circuit 408 senses the analog signal 216 between the positive output and the negative output of the differential multiplexer 204 and feeds the analog signal 216 back through the compensation network 400 with opposite polarity. In the example of FIG. 4, the ground terminal 406 is implemented by the ground terminal 306.

In the illustrated example of FIG. 4, the cancellation circuit 408 includes components to mitigate the in-phase and quadrature components of IMD₃ and HD₃ non-linearity components. In the example of FIG. 4, the in-phase components of the cancellation circuit 408 include the resistor 410, the transistor 414, the transistor 418, and the current source circuit 420. Also, in the example of FIG. 4, the quadrature components of the cancellation circuit 408 include the resistor 422, the transistor 426, the transistor 428, the capacitor 432, and the current source circuit 434. As described above, the cancellation circuit 408 senses the signal at the positive output of the differential multiplexer 204 and feeds the signal at the negative output of the differential multiplexer 204 through the cancellation circuit 408.

Sensing the analog signal 216 and feeding the analog signal 216 through the compensation network 400 with reversed polarity introduces a phase shift (φ₀) between (1) the IMD₃ components generated by the cancellation circuit 408 and (2) the IMD₃ components present in the analog signal 216. Also, sensing the analog signal 216 and feeding the analog signal 216 through the compensation network 400 with reversed polarity introduces three times the phase shift (φ₀) (3φ₀) between (1) the HD₃ components generated by the cancellation circuit 408 and (2) the HD₃ components present in the analog signal 216. As described above, the DAC 200 operates over an 18 GHz bandwidth where the frequency of the analog signal 216 can range from 0 Hz to 18 GHz.

For a first frequency range between 0 Hz and approximately 3 GHz, both IMD₃ and HD₃ components are present in the analog signal 216 in the first frequency range. For a second frequency range between approximately 3 GHz and approximately 6 GHz, both IMD₃ and HD₃ components are present in the analog signal 216 in the second frequency range. For a third frequency range between approximately 6 GHz and approximately 18 GHz, IMD₃ components are present in the analog signal 216 in the third frequency range and HD₃ components are not present in the analog signal 216 in the third frequency range.

In the first frequency range (zone 1: 0 Hz-3 GHz), the phase shift (φ₀) is small and the IMD₃ and HD₃ components generated by the cancellation circuit 408 cancel out the IMD₃ and HD₃ components present in the analog signal 216. For example, the IMD₃ and HD₃ components generated by the in-phase components of the cancellation circuit 408 dominate compensation. Specifically, a current (I_{BI}) through the transistor 416 is to compensate for a third-order intermodulation distortion component (IMD₃ component) and a third-order harmonic distortion component (HD₃ component) of the analog signal 216 from 0 Hz to 3 GHz.

In the third frequency range (zone 3: 6 GHz-18 GHz), the phase shift (φ₀) is significantly high and the IMD₃ components generated by the cancellation circuit 408 cancel out the IMD₃ components present in the analog signal 216. For example, the IMD₃ components generated by the quadrature components of the cancellation circuit 408 dominate compensation. Specifically, a current (I_{BQ}) through the transistor 428 is to compensate for a third-order intermodulation distortion component (IMD₃ component) of the analog signal 216 from 6 GHz to 18 GHz. As described above, when the analog signal 216 has a frequency in the third frequency range (zone 3: 6 GHz-18 GHz), HD₃ components are not present in the analog signal 216 in the third frequency range.

In the second frequency range (zone 2: 3 GHz-6 GHz), the phase shift (φ₀) is significantly high. For example, when frequency of the analog signal 216 is 6 GHz, the phase shift (φ₀) is approximately 6.7 degrees. As such, the relative phase shift between the IMD₃ components and the HD₃ components generated by the cancellation circuit 408 is approximately 13.4 degrees (2φ₀). In some examples, when frequency of the analog signal 216 is 6 GHz, the phase shift (φ₀) is approximately 12 degrees. In such examples, the relative phase shift between the IMD₃ components and the HD₃ components generated by the cancellation circuit 408 is approximately 24 degrees (2φ₀). Thus, the IMD₃ and HD₃ components generated by the cancellation circuit 408 may not cancel out the IMD₃ and HD₃ components present in the analog signal 216.

FIG. 5 is a schematic diagram of an example implementation of the compensation circuit 400 of FIG. 4 including a first example lead compensator (LC) circuit 502₁ and a second example LC circuit 502₂. In the example of FIG. 5, the second terminal of the capacitor 402 is coupled to the positive output of the differential multiplexer 204 and the first terminal of the capacitor 402 is coupled to the input of the LC circuit 502₁. In the example of FIG. 5, the LC circuit 502₁ is implemented by at least one of analog circuitry or digital circuitry. For example, the LC circuit 502₁ is implemented by passive analog components. An example LC circuit that can implement the LC circuit 502₁ is illustrated in FIG. 7. In the example of FIG. 5, the input of the LC circuit 502₁ is coupled to the first terminal of the capacitor 402 and the output of the LC circuit 502₁ is coupled to the control terminal of the transistor 414.

In the illustrated example of FIG. 5, the second terminal of the capacitor 404 is coupled to the positive output of the differential multiplexer 204 and the first terminal of the capacitor 404 is coupled to the input of the LC circuit 502₂. In the example of FIG. 5, the LC circuit 502₂ is implemented by at least one of analog circuitry or digital circuitry. For example, the LC circuit 502₂ is implemented by passive analog components. An example LC circuit that can implement the LC circuit 502₂ is illustrated in FIG. 7. In the example of FIG. 5, the input of the LC circuit 502₂ is coupled to the first terminal of the capacitor 404 and the output of the LC circuit 502₂ is coupled to the control terminal of the transistor 426.

As described above, in the second frequency range (zone 2: 3 GHz-6 GHz), the phase shift (φ₀) is significantly high, introducing a non-negligible relative phase shift (2φ₀) between the IMD₃ components and the HD₃ components generated by the cancellation circuit 408. As such, the IMD₃ and HD₃ components generated by the cancellation circuit 408 may not cancel out the IMD₃ and HD₃ components present in the analog signal 216.

Advantageously, the LC circuits 502₁, 502₂ introduce a phase shift (φ₁) in the second frequency range (zone 2: 3 GHz-6 GHz) to cancel the phase shift (φ₀) between (1) the IMD₃ components generated by the cancellation circuit 408 and (2) the IMD₃ components present in the analog signal 216 as well as three times the phase shift (φ₀) (3φ₀) between (1) the HD₃ components generated by the cancellation circuit 408 and (2) the HD₃ components present in the analog signal 216.

For example, the LC circuit 502₁ senses the analog signal 216, which already includes the phase shift (φ₀), and introduces the phase shift (φ₁) to the signal transmitted to in-phase components of the cancellation circuit 408. As such, the current through the in-phase components of the cancellation circuit 408 and the phase shift introduced by the LC circuit 502₁ compensate for the IMD₃ components present in the analog signal 216. Specifically, a current (I_{BI}) through the transistor 416 and a phase (φ₁) caused by the LC circuit 502₁ are to compensate for a third-order intermodulation distortion component (IMD₃ component) of the analog signal 216 from 3 GHz to 6 GHz.

Also, for example, the LC circuit 502₂ senses the analog signal 216, which already includes the phase shift (φ₀), and introduce the phase shift (φ₁) to the signal transmitted to quadrature components of the cancellation circuit 408. As such, the current through the quadrature components of the cancellation circuit 408 and the phase shift introduced by the LC circuit 502₂ compensate for the HD₃ components present in the analog signal 216. Specifically, a current (I_{BQ}) through the transistor 428 and a phase (φ₁) caused by the LC circuit 502₂ are to compensate for a third-order harmonic distortion component (HD₃ component) of the analog signal 216 from 3 GHz to 6 GHz.

In the illustrated example of FIG. 5, the LC circuits 502₁, 502₂ set the phase shift (φ₁) to approximately zero degrees in the first frequency range (zone 1: 0 Hz-3 GHz). In the example of FIG. 5, the LC circuits 502₁, 502₂ set the phase shift (φ₁) to approximately equal to the absolute value of the phase shift (φ₀) in the second frequency range (zone 2: 3 GHz-6 GHz). Also, in the example of FIG. 5, the LC circuits 502₁, 502₂ set the phase shift (φ₁) to approximately zero degrees in the third frequency range (zone 3: 6 GHz-18 GHz). As such, the compensation network 400 of FIG. 5 compensates for non-linearities in the analog signal 216, including both IMD₃ and HD₃ components when both fall in the frequency range of the analog signal 216, for example for frequencies up to 6 GHz. Thus, the compensation network 400 of FIG. 5 compensates for non-linearities in the analog signal 216 to provide a DAC (for example, the DAC 200 of FIG. 2) with an SFDR of greater than 55 dBc across the 18 GHz bandwidth of the DAC, for example, from 0 Hz to 18 GHz.

In the illustrated examples of FIGS. 4 and 5, the transistors 414, 416, 426, 428 are N-channel MOSFETs. Alternatively, the transistors 414, 416, 426, 428 may be N-channel FETs, N-channel IGBTs, N-channel JFETs, NPN BJTs or, with slight modifications, P-type equivalent devices. The transistors 414, 416, 426, 428 may be depletion mode devices, drain-extended devices, enhancement mode devices, natural transistors or other type of device structure transistors. Furthermore, the transistors 414, 416, 426, 428 may be implemented in/over a Si substrate, a SiC substrate, a GaN substrate, or a GaAs substrate.

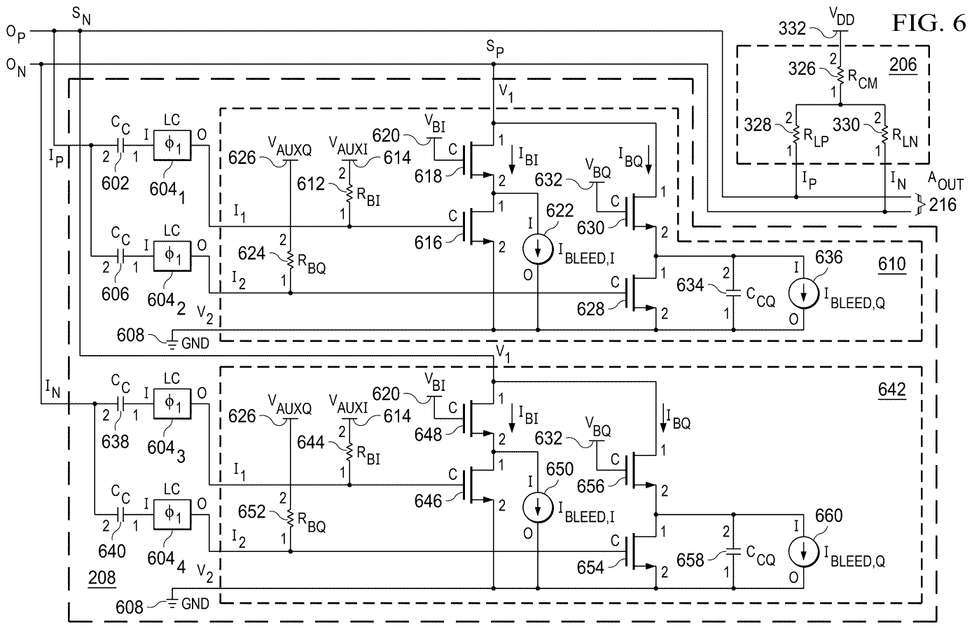

FIG. 6 is a schematic diagram of an example implementation of the compensation network 208 of FIG. 2. In the example of FIG. 6, the compensation network 208 includes a first example capacitor 602, a first example lead compensator (LC) circuit 604₁, a second example capacitor 606, a second example LC circuit 604₂, an example ground terminal 608, and a first example cancellation circuit 610. In the example of FIG. 6, the cancellation circuit 610 includes a first example resistor 612, a first example in-phase biasing terminal 614, a first example transistor 616, a second example transistor 618, a second example in-phase biasing terminal 620, a first example current source circuit 622, a second example resistor 624, a first example quadrature biasing terminal 626, a third example transistor 628, a fourth example transistor 630, a second example quadrature biasing terminal 632, a third example capacitor 634, and a second example current source circuit 636. Also, in the example of FIG. 6, the compensation network 208 also includes a fourth example capacitor 638, a third example LC circuit 604₃, a fifth example capacitor 640, a fourth example LC circuit 604₄, and a second example cancellation circuit 642. In the example of FIG. 6, the cancellation circuit 642 includes a third example resistor 644, the in-phase biasing terminal 614, a fifth example transistor 646, a sixth example transistor 648, the in-phase biasing terminal 620, a third example current source circuit 650, a fourth example resistor 652, the quadrature biasing terminal 626, a seventh example transistor 654, an eighth example transistor 656, the quadrature biasing terminal 632, a sixth example capacitor 658, and a fourth example current source circuit 660.

In the illustrated example of FIG. 6, each of the capacitor 602, the capacitor 606, the resistor 612, the resistor 624, the capacitor 634, the capacitor 638, the capacitor 640, the resistor 644, the resistor 652, and the capacitor 658 has a first terminal and a second terminal. In the example of FIG. 6, each of the LC circuit 604₁, the LC circuit 604₂, the LC circuit 604₃, the LC circuit 604₄, the current source circuit 622, the current source circuit 636, the current source circuit 650, and the current source circuit 660 has an input and an output. Also, in the example of FIG. 6, each of the transistor 616, the transistor 618, the transistor 628, the transistor 630, the transistor 646, the transistor 648, the transistor 654, and the transistor 656 has a control terminal (a gate terminal), a first terminal (a drain terminal), and a second terminal (a source terminal). In the example of FIG. 6, each of the cancellation circuit 610 and the cancellation circuit 642 has a first input, a second input, a first voltage terminal, and a second voltage terminal.

In the illustrated example of FIG. 6, the capacitor 602 has a capacitance of Cc. In the example of FIG. 6, the second terminal of the capacitor 602 is coupled to the positive output of the differential multiplexer 204 and the first terminal of the capacitor 602 is coupled to the input of the LC circuit 604₁. In the example of FIG. 6, the LC circuit 604₁ is implemented by at least one of analog circuitry or digital circuitry. For example, the LC circuit 604₁ is implemented by passive analog components. An example LC circuit that can implement the LC circuit 604₁ is illustrated in FIG. 7. In the example of FIG. 6, the input of the LC circuit 604₁ is coupled to the first terminal of the capacitor 602 and the output of the LC circuit 604₁ is coupled to the control terminal of the transistor 616.

In the illustrated example of FIG. 6, the capacitor 606 has a capacitance of Cc. In the example of FIG. 6, the second terminal of the capacitor 606 is coupled to the positive output of the differential multiplexer 204 and the first terminal of the capacitor 606 is coupled to the input of the LC circuit 604₂. As such, the second terminal of the capacitor 602 and the second terminal of the capacitor 606 are to operate as the positive input of the compensation network 208. In the example of FIG. 6, the LC circuit 604₂ is implemented by at least one of analog circuitry or digital circuitry. For example, the LC circuit 604₂ is implemented by passive analog components. An example LC circuit that can implement the LC circuit 604₂ is illustrated in FIG. 7. In the example of FIG. 6, the input of the LC circuit 604₂ is coupled to the first terminal of the capacitor 606 and the output of the LC circuit 604₂ is coupled to the control terminal of the transistor 628.

In the illustrated example of FIG. 6, the first input of the cancellation circuit 610 is coupled to the output of the LC circuit 604₁ and the second input of the cancellation circuit 610 is coupled to the output of the LC circuit 604₂. In the example of FIG. 6, the first voltage terminal of the cancellation circuit 610 is coupled to the negative output of the differential multiplexer 204 and the second voltage terminal of the cancellation circuit 610 is coupled to the ground terminal 608. For example, the ground terminal 608 is implemented by the ground terminal 306 of FIG. 3. In the example of FIG. 6, the resistor 612 has a resistance of R_{BI}. In the example of FIG. 6, the second terminal of the resistor 612 is coupled to the in-phase biasing terminal 614. For example, the in-phase biasing terminal 614 is at a voltage of V_{AUXI}. In the example of FIG. 6, the first terminal of the resistor 612 is coupled to the control terminal of the transistor 616.

In the illustrated example of FIG. 6, the transistor 616 is an N-channel FET such as an NMOS FET. In the example of FIG. 6, the control terminal of the transistor 616 is coupled to the output of the LC circuit 604₁ and the first terminal of the resistor 612. As such, the control terminal of the transistor 616 is to operate as the first input of the cancellation circuit 610. In the example of FIG. 6, the first terminal of the transistor 616 is coupled to the second terminal of the transistor 618. Also, in the example of FIG. 6, the second terminal of the transistor 616 is coupled to the ground terminal 608.

In the illustrated example of FIG. 6, the transistor 618 is an N-channel FET such as an NMOS FET. In the example of FIG. 6, the control terminal of the transistor 618 is coupled to the in-phase biasing terminal 620. For example, the in-phase biasing terminal 620 is at a voltage of V_{BI}. In the example of FIG. 6, the first terminal of the transistor 618 is coupled to the negative output of the differential multiplexer 204. As such, the first terminal of the transistor 618 is to operate as the first voltage terminal of the cancellation circuit 610. In the example of FIG. 6, the second terminal of the transistor 618 is coupled to the first terminal of the transistor 616. Also, in the example of FIG. 6, the current source circuit 622 provides a current of I_{BLEED, I}. In the example of FIG. 6, the input of the current source circuit 622 is coupled to the second terminal of the transistor 618 and the output of the current source circuit 622 is coupled to the ground terminal 608.

In the illustrated example of FIG. 6, the resistor 624 has a resistance of R_{BQ}. In the example of FIG. 6, the second terminal of the resistor 624 is coupled to the quadrature biasing terminal 626. For example, the quadrature biasing terminal 626 is at a voltage of V_{AUXQ}. In the example of FIG. 6, the first terminal of the resistor 624 is coupled to the control terminal of the transistor 628.

In the illustrated example of FIG. 6, the transistor 628 is an N-channel FET such as an NMOS FET. In the example of FIG. 6, the control terminal of the transistor 628 is coupled to the output of the LC circuit 604₂ and the first terminal of the resistor 624. As such, the control terminal of the transistor 628 is to operate as the second input of the cancellation circuit 610. In the example of FIG. 6, the first terminal of the transistor 628 is coupled to the second terminal of the transistor 630. Also, in the example of FIG. 6, the second terminal of the transistor 628 is coupled to the ground terminal 608.

In the illustrated example of FIG. 6, the transistor 630 is an N-channel FET such as an NMOS FET. In the example of FIG. 6, the control terminal of the transistor 630 is coupled to the quadrature biasing terminal 632. For example, the quadrature biasing terminal 632 is at a voltage of V_{BQ}. In the example of FIG. 6, the first terminal of the transistor 630 is coupled to the first terminal of the transistor 618. Also, in the example of FIG. 6, the second terminal of the transistor 630 is coupled to the first terminal of the transistor 628.

In the illustrated example of FIG. 6, the capacitor 634 has a capacitance of C_{CQ}. In the example of FIG. 6, the second terminal of the capacitor 634 is coupled to the second terminal of the transistor 630. Also, in the example of FIG. 6, the first terminal of the capacitor 634 is coupled to the ground terminal 608. In the example of FIG. 6, the current source circuit 636 provides a current of I_{BLEED, Q}. In the example of FIG. 6, the input of the current source circuit 636 is coupled to the second terminal of the transistor 630 and the output of the current source circuit 636 is coupled to the ground terminal 608. As such, the second terminal of the transistor 616, the output of the current source circuit 622, the second terminal of the transistor 628, the first terminal of the capacitor 634, and the output of the current source circuit 636 are to operate as the second voltage terminal of the cancellation circuit 610.

In the illustrated example of FIG. 6, the capacitor 638 has a capacitance of Cc. In the example of FIG. 6, the second terminal of the capacitor 638 is coupled to the negative output of the differential multiplexer 204 and the first terminal of the capacitor 638 is coupled to the input of the LC circuit 604₃. In the example of FIG. 6, the LC circuit 604₃ is implemented by at least one of analog circuitry or digital circuitry. For example, the LC circuit 604₃ is implemented by passive analog components. An example LC circuit that can implement the LC circuit 604₃ is illustrated in FIG. 7. In the example of FIG. 6, the input of the LC circuit 604₃ is coupled to the first terminal of the capacitor 638 and the output of the LC circuit 604₃ is coupled to the control terminal of the transistor 646.

In the illustrated example of FIG. 6, the capacitor 640 has a capacitance of Cc. In the example of FIG. 6, the second terminal of the capacitor 640 is coupled to the negative output of the differential multiplexer 204 and the first terminal of the capacitor 640 is coupled to the input of the LC circuit 604₄. As such, the second terminal of the capacitor 638 and the second terminal of the capacitor 640 are to operate as the negative input of the compensation network 208. In the example of FIG. 6, the LC circuit 604₄ is implemented by at least one of analog circuitry or digital circuitry. For example, the LC circuit 604₄ is implemented by passive analog components. An example LC circuit that can implement the LC circuit 604₄ is illustrated in FIG. 7. In the example of FIG. 6, the input of the LC circuit 604₄ is coupled to the first terminal of the capacitor 640 and the output of the LC circuit 604₄ is coupled to the control terminal of the transistor 654.

In the illustrated example of FIG. 6, the first input of the cancellation circuit 642 is coupled to the output of the LC circuit 604₃ and the second input of the cancellation circuit 642 is coupled to the output of the LC circuit 604₄. In the example of FIG. 6, the first voltage terminal of the cancellation circuit 642 is coupled to the positive output of the differential multiplexer 204 and the second voltage terminal of the cancellation circuit 642 is coupled to the ground terminal 608. In the example of FIG. 6, the resistor 644 has a resistance of R_{BI}. In the example of FIG. 6, the second terminal of the resistor 644 is coupled to the in-phase biasing terminal 614. Also, in the example of FIG. 6, the first terminal of the resistor 644 is coupled to the control terminal of the transistor 646.

In the illustrated example of FIG. 6, the transistor 646 is an N-channel FET such as an NMOS FET. In the example of FIG. 6, the control terminal of the transistor 646 is coupled to the output of the LC circuit 604₃ and the first terminal of the resistor 644. As such, the control terminal of the transistor 646 is to operate as the first input of the cancellation circuit 642. In the example of FIG. 6, the first terminal of the transistor 646 is coupled to the second terminal of the transistor 648. Also, in the example of FIG. 6, the second terminal of the transistor 646 is coupled to the ground terminal 608.

In the illustrated example of FIG. 6, the transistor 648 is an N-channel FET such as an NMOS FET. In the example of FIG. 6, the control terminal of the transistor 648 is coupled to the in-phase biasing terminal 620. Also, in the example of FIG. 6, the first terminal of the transistor 648 is coupled to the positive output of the differential multiplexer 204. As such, the first terminal of the transistor 648 is to operate as the first voltage terminal of the cancellation circuit 642. In the example of FIG. 6, the second terminal of the transistor 648 is coupled to the first terminal of the transistor 646. Also, in the example of FIG. 6, the current source circuit 650 provides a current of I_{BLEED, I}. In the example of FIG. 6, the input of the current source circuit 650 is coupled to the second terminal of the transistor 648 and the output of the current source circuit 650 is coupled to the ground terminal 408.

In the illustrated example of FIG. 6, the resistor 652 has a resistance of R_{BQ}. In the example of FIG. 6, the second terminal of the resistor 652 is coupled to the quadrature biasing terminal 626. Also, in the example of FIG. 6, the first terminal of the resistor 652 is coupled to the control terminal of the transistor 654. In the example of FIG. 6, the transistor 654 is an N-channel FET such as an NMOS FET. Also, in the example of FIG. 6, the control terminal of the transistor 654 is coupled to the output of the LC circuit 604₄ and the first terminal of the resistor 652. As such, the control terminal of the transistor 654 is to operate as the second input of the cancellation circuit 642. In the example of FIG. 6, the first terminal of the transistor 654 is coupled to the second terminal of the transistor 656 and the second terminal of the transistor 654 is coupled to the ground terminal 608.

In the illustrated example of FIG. 6, the transistor 656 is an N-channel FET such as an NMOS FET. In the example of FIG. 6, the control terminal of the transistor 656 is coupled to the quadrature biasing terminal 632. Also, in the example of FIG. 6, the first terminal of the transistor 656 is coupled to the first terminal of the transistor 648. In the example of FIG. 6, the second terminal of the transistor 656 is coupled to the first terminal of the transistor 654.

In the illustrated example of FIG. 6, the capacitor 658 has a capacitance of C_{CQ}. In the example of FIG. 6, the second terminal of the capacitor 658 is coupled to the second terminal of the transistor 656. Also, in the example of FIG. 6, the first terminal of the capacitor 658 is coupled to the ground terminal 408. In the example of FIG. 6, the current source circuit 660 provides a current of I_{BLEED, Q}. In the example of FIG. 6, the input of the current source circuit 660 is coupled to the second terminal of the transistor 656 and the output of the current source circuit 660 is coupled to the ground terminal 408. As such, the second terminal of the transistor 646, the output of the current source circuit 650, the second terminal of the transistor 654, the first terminal of the capacitor 658, and the output of the current source circuit 660 are to operate as the second voltage terminal of the cancellation circuit 642.

In the illustrated example of FIG. 6, as described above, transconductance transistors of DAC cores can introduce non-linearities, such as IMD₃ components and HD₃ components, that dominate the overall non-linearity in an analog signal provided by an interleaved DAC. To compensate for IMD₃ and HD₃ non-linearity components, the cancellation circuit 610 and the cancellation circuit 642 sense the analog signal 216 between the positive output and the negative output of the differential multiplexer 204 and feed the analog signal 216 back through the compensation network 208 with opposite polarity. In the example of FIG. 6, each of the cancellation circuit 610 and the cancellation circuit 642 includes components to mitigate the in-phase and quadrature components of IMD₃ and HD₃ non-linearity components.

In the illustrated example of FIG. 6, the in-phase components of the cancellation circuit 610 include the resistor 612, the transistor 616, the transistor 618, and the current source circuit 622. In the example of FIG. 6, the quadrature components of the cancellation circuit 610 include the resistor 624, the transistor 628, the transistor 630, the capacitor 634, and the current source circuit 636. Also, in the example of FIG. 6, the in-phase components of the cancellation circuit 642 include the resistor 644, the transistor 646, the transistor 648, and the current source circuit 650. In the example of FIG. 6, the quadrature components of the cancellation circuit 642 include the resistor 652, the transistor 654, the transistor 656, the capacitor 658, and the current source circuit 660.

In the illustrated example of FIG. 6, the cancellation circuit 610 senses the signal at the positive output of the differential multiplexer 204 and feeds the signal at the negative output of the differential multiplexer 204 through the cancellation circuit 610. Also, for example, the cancellation circuit 642 senses the signal at the negative output of the differential multiplexer 204 and feeds the signal at the positive output of the differential multiplexer 204 through the cancellation circuit 642. Sensing the analog signal 216 and feeding the analog signal 216 through the compensation network 208 with reversed polarity introduces a phase shift (φ₀) between (1) the IMD₃ components generated by the cancellation circuit 610 and the cancellation circuit 642 and (2) the IMD₃ components present in the analog signal 216. Also, sensing the analog signal 216 and feeding the analog signal 216 through the compensation network 208 with reversed polarity introduces three times the phase shift (φ₀) (3φ₀) between (1) the HD₃ components generated by the cancellation circuit 610 and the cancellation circuit 642 and (2) the HD₃ components present in the analog signal 216.

As described above, the DAC 200 operates over an 18 GHz bandwidth where the frequency of the analog signal 216 can range from 0 Hz to 18 GHz. For a first frequency range between 0 Hz and approximately 3 GHz, both IMD₃ and HD₃ components are present in the analog signal 216 in the first frequency range. For a second frequency range between approximately 3 GHz and approximately 6 GHz, both IMD₃ and HD₃ components are present in the analog signal 216 in the second frequency range. For a third frequency range between approximately 6 GHz and approximately 18 GHz, IMD₃ components are present in the analog signal 216 in the third frequency range and HD₃ components are not present in the analog signal 216 in the third frequency range.

In the first frequency range (zone 1: 0 Hz-3 GHz), the phase shift (φ₀) is small and the IMD₃ and HD₃ components generated by the cancellation circuit 610 and the cancellation circuit 642 cancel out the IMD₃ and HD₃ components present in the analog signal 216. For example, the IMD₃ and HD₃ components generated by the in-phase components of the cancellation circuit 610 and the cancellation circuit 642 dominate compensation. Specifically, a first current (I_{BI}) through the transistor 618 and a second current (I_{BI}) through the transistor 648 are to compensate for a third-order intermodulation distortion component (IMD₃ component) and a third-order harmonic distortion component (HD₃ component) of the analog signal 216 from 0 Hz to 3 GHz.

In the third frequency range (zone 3: 6 GHz-18 GHz), the phase shift (φ₀) is significantly high and the IMD₃ components generated by the cancellation circuit 610 and the cancellation circuit 642 cancel out the IMD₃ components present in the analog signal 216. For example, the IMD₃ components generated by the quadrature components of the cancellation circuit 610 and the cancellation circuit 642 dominate compensation. Specifically, a first current (I_{BQ}) through the transistor 630 and a second current (I_{BQ}) through the transistor 656 are to compensate for a third-order intermodulation distortion component (IMD₃ component) of the analog signal 216 from 6 GHz to 18 GHz. As described above, when the analog signal 216 has a frequency in the third frequency range (zone 3: 6 GHz-18 GHz), HD₃ components are not present in the analog signal 216 in the third frequency range.

In the second frequency range (zone 2: 3 GHz-6 GHz), the phase shift (φ₀) is significantly high. For example, when frequency of the analog signal 216 is 6 GHz, the phase shift (φ₀) is approximately 6.7 degrees. As such, the relative phase shift between the IMD₃ components and the HD₃ components generated by the cancellation circuit 610 and the cancellation circuit 642 is approximately 13.4 degrees (2φ₀). In some examples, when frequency of the analog signal 216 is 6 GHz, the phase shift (φ₀) is approximately 12 degrees. In such examples, the relative phase shift between the IMD₃ components and the HD₃ components generated by the cancellation circuit 610 and the cancellation circuit 642 is approximately 24 degrees (2φ₀). Thus, the IMD₃ and HD₃ components generated by the cancellation circuit 610 and the cancellation circuit 642 may not cancel out the IMD₃ and HD₃ components present in the analog signal 216.

Advantageously, the LC circuits 604₁-604₄ introduce a phase shift (φ₁) in the second frequency range (zone 2: 3 GHz-6 GHz) to cancel the phase shift (φ₀) between (1) the IMD₃ components generated by the cancellation circuit 610 and the cancellation circuit 642 and (2) the IMD₃ components present in the analog signal 216 as well as three times the phase shift (φ₀) (3φ₀) between (1) the HD₃ components generated by the cancellation circuit 610 and the cancellation circuit 642 and (2) the HD₃ components present in the analog signal 216. For example, the LC circuit 604₁ and the LC circuit 604₃ sense the analog signal 216, which already includes the phase shift (φ₀), and introduce the phase shift (φ₁) to the signal transmitted to in-phase components of the cancellation circuit 610 and the cancellation circuit 642, respectively.

As such, the currents through the in-phase components of the cancellation circuit 610 and the cancellation circuit 642 and the phase shifts introduced by the LC circuit 604₁ and the LC circuit 604₃ compensate for the IMD₃ components present in the analog signal 216. Specifically, a first current (I_{BI}) through the transistor 618, a second current (I_{BI}) through the transistor 648, a first phase (φ₁) caused by the LC circuit 604₁, and a second phase (φ₁) caused by the LC circuit 604₃ are to compensate for a third-order intermodulation distortion component (IMD₃ component) of the analog signal 216 from 3 GHz to 6 GHz.

Also, for example, the LC circuit 604₂ and the LC circuit 604₄ sense the analog signal 216, which already includes the phase shift (φ₀), and introduce the phase shift (φ₁) to the signal transmitted to quadrature components of the cancellation circuit 610 and the cancellation circuit 642, respectively. As such, the currents through the quadrature components of the cancellation circuit 610 and the cancellation circuit 642 and the phase shifts introduced by the LC circuit 604₂ and the LC circuit 604₄ compensate for the HD₃ components present in the analog signal 216. Specifically, a first current (I_{BQ}) through the transistor 630, a second current (I_{BQ}) through the transistor 656, a first phase (φ₁) caused by the LC circuit 604₂, and a second phase (φ₁) caused by the LC circuit 604₄ are to compensate for a third-order harmonic distortion component (HD₃ component) of the analog signal 216 from 3 GHz to 6 GHz.

In the illustrated example of FIG. 6, the LC circuits 604₁-604₄ set the phase shift (φ₁) to approximately zero degrees in the first frequency range (zone 1: 0 Hz-3 GHz). In the example of FIG. 6, the LC circuits 604₁-604₄ set the phase shift (φ₁) to approximately equal to the absolute value of the phase shift (φ₀) in the second frequency range (zone 2: 3 GHz-6 GHz). Also, in the example of FIG. 6, the LC circuits 604₁-604₄ set the phase shift (φ₁) to approximately zero degrees in the third frequency range (zone 3: 6 GHz-18 GHz). As such, the compensation network 208 compensates for non-linearities in the analog signal 216, including both IMD₃ and HD₃ components when both fall in the frequency range of the analog signal 216, for example for frequencies up to 6 GHz. Thus, the compensation network 208 compensates for non-linearities in the analog signal 216 to provide the DAC 200 with an SFDR of greater than 55 dBc across the 18 GHz bandwidth of the DAC 200, for example, from 0 Hz to 18 GHz.

In the illustrated examples of FIG. 6, the transistors 616, 618, 628, 630, 646, 648, 654, 656 are N-channel MOSFETs. Alternatively, the transistors 616, 618, 628, 630, 646, 648, 654, 656 may be N-channel FETs, N-channel IGBTs, N-channel JFETs, NPN BJTs or, with slight modifications, P-type equivalent devices. The transistors 616, 618, 628, 630, 646, 648, 654, 656 may be depletion mode devices, drain-extended devices, enhancement mode devices, natural transistors or other type of device structure transistors. Furthermore, the transistors 616, 618, 628, 630, 646, 648, 654, 656 may be implemented in/over a Si substrate, a SiC substrate, a GaN substrate, or a GaAs substrate.

FIG. 7 is schematic diagram of an example LC circuit 700 that can implement one or more of the LC circuits 502₁, 502₂ of FIG. 5 or one or more of the LC circuits 604₁-604₄ of FIG. 6. In the example of FIG. 7, the LC circuit 700 includes a first example capacitor 702, a first example resistor 704, a second example resistor 706, a second example capacitor 708, a third example capacitor 710, and an example ground terminal 712. In the example of FIG. 7, each of the capacitor 702, the resistor 704, the resistor 706, the capacitor 708, and the capacitor 710 has a first terminal and a second terminal.

In the illustrated example of FIG. 7, the capacitor 702 has a capacitance of C₁. In the example of FIG. 7, the second terminal of the capacitor 702 is to operate as the input of the LC circuit 700. Also, in the example of FIG. 7, the first terminal of the capacitor 702 is to operate as the output of the LC circuit 700. In the example of FIG. 7, the resistor 704 has a resistance of R. For example, the resistor 704 is a variable resistor that can be tuned. In the example of FIG. 7, the second terminal of the resistor 704 is coupled to the first terminal of the capacitor 702. Also, in the example of FIG. 7, the first terminal of the resistor 704 is coupled to the second terminal of the capacitor 708.

In the illustrated example of FIG. 7, the resistor 706 has a resistance of R_{BIAS}. In the example of FIG. 7, the second terminal of the resistor 706 is coupled to an example supply terminal 714. For example, the supply terminal 714 is at a voltage of V_{b}. In the example of FIG. 7, the voltage V_{b} is a variable voltage that can be tuned. For example, when the LC circuit 700 implements the LC circuit 502₁, V_{b} is equal to V_{AUXI}, for example, the supply terminal 714 is implemented by the in-phase biasing terminal 412. Also, for example, when the LC circuit 700 implements at least one of the LC circuit 604₁, or the LC circuit 604₃, V_{b} is equal to V_{AUXI}, for example, the supply terminal 714 is implemented by the in-phase biasing terminal 614. In examples when the LC circuit 700 implements the LC circuit 502₂, V_{b} is equal to V_{AUXQ}, for example, the supply terminal 714 is implemented by the quadrature biasing terminal 424. Also, for example, when the LC circuit 700 implements at least one of the LC circuit 604₂ or the LC circuit 604₄, V_{b} is equal to V_{AUXQ}, for example, the supply terminal 714 is implemented by the quadrature biasing terminal 626. In the example of FIG. 7, the first terminal of the resistor 706 is coupled to the first terminal of the resistor 704 and the second terminal of the capacitor 708.

In the illustrated example of FIG. 7, the capacitor 708 has a capacitance of C. For example, the capacitor 708 is a variable capacitor that can be tuned. In the example of FIG. 7, the second terminal of the capacitor 708 is coupled to the first terminal of the resistor 704 and the first terminal of the resistor 706. Also, in the example of FIG. 7, the first terminal of the capacitor 708 is coupled to the ground terminal 712. In the example of FIG. 7, the capacitor 710 has a capacitance of C₂. Also, in the example of FIG. 7, the second terminal of the capacitor 710 is coupled to the first terminal of the capacitor 702 and the first terminal of the capacitor 710 is coupled to the ground terminal 712.

Equation 2 represents the transfer function H(s) of the LC circuit 700. In Equation 2, the symbol ∥ represents the parallel combination of (1) the capacitance C and (2) the sum of the capacitances C₁ and C₂.

$$Equation 2$$

$$H ( s ) = \frac{{C}_{1} ( 1 + sCR )}{( C + {C}_{1} + {C}_{2} ) ( 1 + sC ‖ ( {C}_{1} + {C}_{2} ) R )} = \frac{C ( 1 + sCR )}{( C + {C}_{1} + {C}_{2} + sCR ( {C}_{1} + {C}_{2} ) )}$$

In the illustrated example of FIG. 7, the LC circuit 700 senses a signal at the input of the LC circuit 700 and applies a phase shift (φ₁) to the signal according to Equation 2. Also, the LC circuit 700 provides the phase shifted signal to a cancellation circuit (one or more of the cancellation circuit 408, the cancellation circuit 610, or the cancellation circuit 642) at the output of the LC circuit 700. According to Equation 2, the LC circuit 700 has one zero and one pole. As such, the LC circuit 700 induces a positive phase shift of approximately 6 to 10 degrees in the second frequency range (zone 2: 3 GHz-6 GHz) and a phase shift of approximately 0 degrees in the first frequency range (zone 1: 0 Hz-3 GHz) and the third frequency range (zone 3: 6 GHz-18 GHz).

As described above, the resistance R of the resistor 704 and the capacitance C of the capacitor 708 are tunable, for example, programmable, to facilitate control of the phase shift (i) in the second frequency range. Also, the resistance R_{BIAS} of the resistor 706 is large (e.g., 60 kilo-ohms (kΩ)) to bias the input of the cancellation circuit (one of the cancellation circuit 408, the cancellation circuit 610, or the cancellation circuit 642) to which the LC circuit 700 provides the phase shifted signal. By implementing the LC circuits 502₁, 502₂ according to the LC circuit 700 of FIG. 7, the LC circuits 502₁, 502₂ mitigate non-linearities in the analog signal 216 throughout the second frequency range of the 18 GHz bandwidth of a DAC (for example, the DAC 200). Likewise, by implementing the LC circuits 604₁-604₄ according to the LC circuit 700 of FIG. 7, the LC circuits 604₁-604₄ mitigate non-linearities in the analog signal 216 throughout the second frequency range of the 18 GHz bandwidth of the DAC 200.

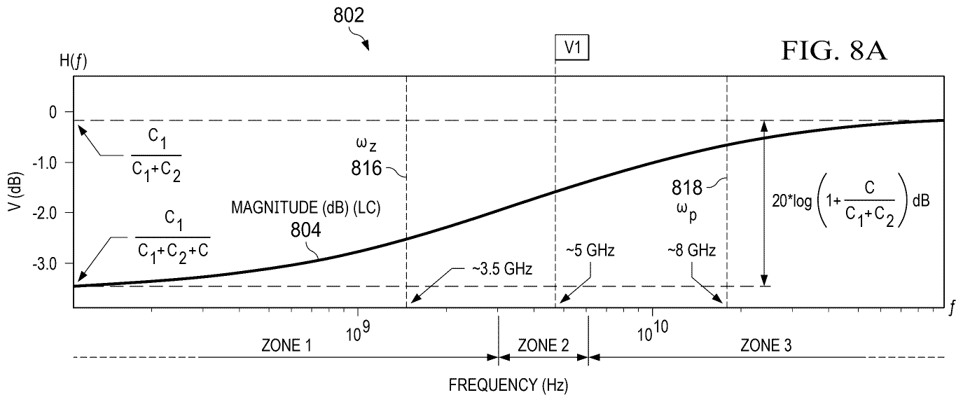

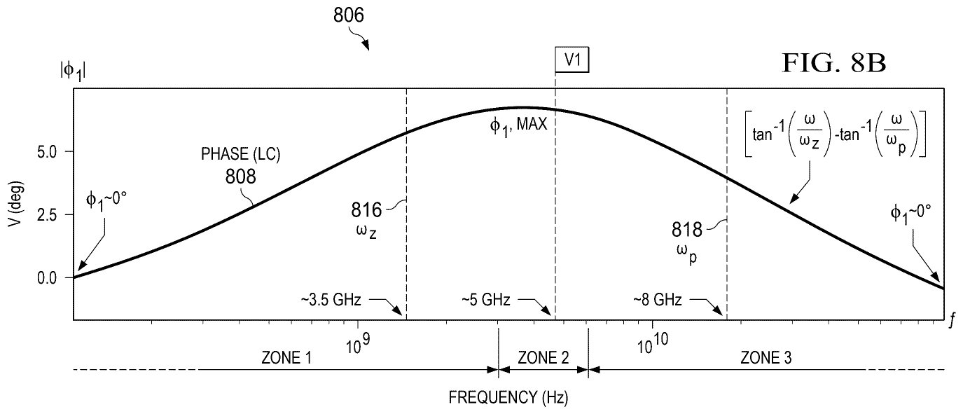

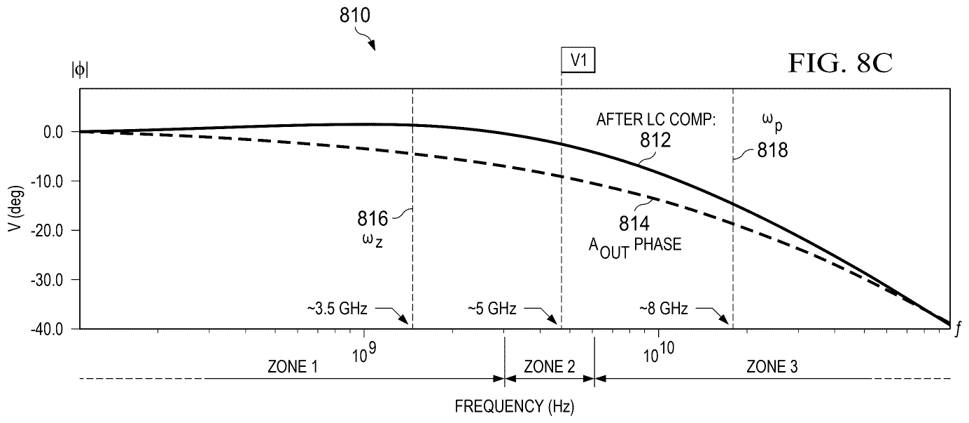

FIG. 8A is a graphical illustration of an example plot 802 including an example magnitude response 804 of the LC circuit 700 of FIG. 7. FIG. 8B is a graphical illustration of an example plot 806 including an example phase response 808 of the LC circuit 700 of FIG. 7. FIG. 8C is a graphical illustration of an example plot 810 including a first example phase response 812 of the DAC 200 of FIG. 2 with the LC circuits 604₁-604₄ of FIG. 6 and a second example phase response 814 of the DAC 200 of FIG. 2 without the LC circuits 604₁-604₄ of FIG. 6. FIGS. 8A, 8B, and 8C are collectively referred to as FIG. 8. The plots illustrated in FIG. 8 correspond to an example trim setting for the resistor 704 and the capacitor 708 of the LC circuits 604₁-604₄.

In the illustrated example of FIG. 8, the magnitude response 804 depicts the magnitude, measured as volts (V) in decibels (dB), of an output signal from the LC circuit 700 with respect to frequency, measured in Hz. In the example of FIG. 8, the phase response 808 depicts the phase, measured in degrees, of the output signal from the LC circuit 700 with respect to frequency, measured in Hz. Also, in the example of FIG. 8, the phase response 812 depicts the phase, measured in degrees, of the analog signal 216 when the LC circuits 604₁-604₄ are included in the DAC 200 with respect to frequency, measured in Hz. In the example of FIG. 8, the phase response 814 depicts the phase, measured in degrees, of the analog signal 216 from the DAC 200 when the LC circuits 604₁-604₄ are not included in the DAC 200 with respect to frequency, measured in Hz.

In the illustrated example of FIG. 8, for the first frequency range (zone 1: 0 Hz-3 GHz) and the third frequency range (zone 3: 6 GHz-18 GHz), the phase response 808 of the LC circuit 700 is approximately zero degrees. Also, as described above, for analog signals in the third frequency range (zone 3: 6 GHz-18 GHz), HD₃ components are not present in the third frequency range. In the example of FIG. 8, for the second frequency range (zone 2: 3 GHz-6 GHz), the phase response 808 of the LC circuit 700 reaches a peak of approximately 6.7 degrees.

As depicted in the phase response 812 and the phase response 814, in the second frequency range (zone 2: 3 GHz-6 GHz), the phase shift (φ₁) added by the LC circuits 604₁-604₄ compensates the phase of the analog signal 216. For example, the phase shift (φ₁) added by the LC circuits 604₁-604₄ causes the phase of the analog signal 216 to go from approximately −7.1 degrees to approximately −0.4 degrees at approximately 5 GHz. As such, the phase of the analog signal 216 remains almost flat (for example, approximately zero degrees) through 6 GHz. Accordingly, the LC circuits 604₁-604₄ reduce the skew between (1) the non-linear components generated by the cancellation circuit 610 and the cancellation circuit 642 and (2) the non-linear components present in the analog signal 216 for frequencies in the second frequency range (zone 2: 3 GHz-6 GHz).

In the illustrated example of FIG. 8, the magnitude response 804 of the LC circuit 700 does not vary greatly across frequency. For example, between the first frequency range (zone 1: 0 Hz-3 GHz) and the third frequency range (zone 3: 6 GHz-18 GHz), the magnitude response 804 of the LC circuit 700 varies by

$$20 log ( 1 + \frac{C}{{C}_{1} + {C}_{2}} ) dB$$

across frequency with an upper value of

$$\frac{{C}_{1}}{{C}_{1} + {C}_{2}}$$

and a lower value of

$$\frac{{C}_{1}}{{C}_{1} + {C}_{2} + C} .$$

In the example of FIG. 8, the magnitude response 804 of the LC circuit 700 varies by approximately ±3.25 dB across frequency. The variation in the magnitude response 804 of the LC circuit 700 can be adjusted (for example, to be minimized) by maintaining the position of an example zero 816 and an example pole 818 close together in the frequency spectrum. The position of the zero 816 and the pole 818 can be controlled by varying the capacitance C of the capacitor 708. In the example of FIG. 8, the zero 816 is positioned at 3.5 GHz and the pole 818 is positioned at 8 GHz. In general, the position of the zero 816 is defined according to Equation 3 below and the position of the pole 818 is defined according to Equation 4 below.

$${ω}_{z} = \frac{1}{RC} \qquad Equation 3$$

$${ω}_{p} = \frac{1}{R ( \frac{C ( {C}_{1} + {C}_{2} )}{C + {C}_{1} + {C}_{2}} )} \qquad Equation 4$$

As described herein, the compensation network 208 of FIG. 2 compensates for non-linearity in the analog signal 216 provided by the differential multiplexer 204. Table 1 lists the magnitude of IMD₃ and HD₃ components in an analog signal provided by an interleaved DAC at different frequencies when different levels of compensation are implemented. In Table 1, the magnitude of the IMD₃ and HD₃ components is represented in dBc.

TABLE 1

| | No | | Compensation with the | | Compensation with the | |
|---|---|---|---|---|---|---|
| | Compensation | | cancellation circuits 610, 642 | | compensation network 208 | |
| | IMD₃ | HD₃ | IMD₃ | HD₃ | IMD₃ | HD₃ |
| | (dBc) | (dBc) | (dBc) | (dBc) | (dBc) | (dBc) |
| Zone1: 1 GHz | −51.1 | −50.5 | −64.1 | −62.0 | −63.1 | −62.5 |
| Zone2: 5 GHz | −51.4 | −50.4 | −61.9 | −52.5 | −64.5 | −59.2 |
| Zone3: 16 GHz | −52.0 | N/A | −56.1 | N/A | −56.7 | N/A |

As shown above, Table 1 lists the magnitude of IMD₃ and HD₃ components in an analog signal provided by an interleaved DAC at 1 GHz (zone 1), 5 GHz (zone 2), and 16 GHz (zone 3) when no compensation is implemented. Also, Table 1 lists the magnitude of IMD₃ and HD₃ components in an analog signal provided by an interleaved DAC at 1 GHz (zone 1), 5 GHz (zone 2), and 16 GHz (zone 3) when compensation is provided by the cancellation circuit 610 and the cancellation circuit 642 of FIG. 3B. Table 1 also lists the magnitude of IMD₃ and HD₃ components in the analog signal 216 provided by the DAC 200 at 1 GHz (zone 1), 5 GHz (zone 2), and 16 GHz (zone 3) when the compensation network 208 of FIG. 2.

As shown in Table 1, the compensation network 208 and the cancellation circuits 610, 642 provide similar compensation for frequencies in the first frequency range (zone 1) and the third frequency range (zone 3). For example, in the first frequency range (zone 1), (1) the magnitude of the IMD₃ and HD₃ components is −64.1 dBc and −62.0 dBc, respectively, with the cancellation circuits 610, 642 and (2) the magnitude of the IMD₃ and HD₃ components is −63.1 dBc and −62.5 dBc, respectively, with the compensation network 208. Conversely, in the first frequency range (zone 1), the magnitude of the IMD₃ and HD₃ components is −51.1 dBc and −50.5 dBc, respectively, without compensation.

As shown in Table 1, in the third frequency range (zone 3), (1) the magnitude of the IMD₃ components is −56.1 dBc, with the cancellation circuits 610, 642 and (2) the magnitude of the IMD₃ components is −56.7 dBc, with the compensation network 208. Conversely, in the third frequency range (zone 3), the magnitude of the IMD₃ components is −52.0 dBc without compensation. As described above, for analog signals in the third frequency range (zone 3), HD₃ components are not in the third frequency range (zone 3).

Also, as shown in Table 1, in the second frequency range (zone 2), the LC circuits 604₁-604₄ of the compensation network 208 provide additional compensation in addition to the compensation provided by the cancellation circuits 610, 642. For example, in the second frequency range (zone 2), (1) the magnitude of the IMD₃ and HD₃ components is −61.9 dBc and −52.5 dBc, respectively, with the cancellation circuits 610, 642 and (2) the magnitude of the IMD₃ and HD₃ components is −64.5 dBc and −59.2 dBc, respectively, with the compensation network 208. Conversely, in the second frequency range (zone 2), the magnitude of the IMD₃ and HD₃ components is −51.4 dBc and −50.4 dBc, respectively, without compensation.

While an example manner of implementing the DACs 116₁-116_{N} of FIG. 1 is illustrated in FIG. 2, one or more of the elements, processes, or devices illustrated in FIG. 2 may be combined, divided, re-arranged, omitted, eliminated, or implemented in any other way. Further, the example DAC cores 202₁-202_{D}, the example differential multiplexer 204, the example output termination network 206, the example compensation network 208, the example control circuitry 210, the example sampling switches 212₁-212_{D}, or, more generally, the example DAC 200 of FIG. 2, may be implemented by hardware alone or by hardware in combination with software and firmware. Thus, for example, any of the example DAC cores 202₁-202_{D}, the example differential multiplexer 204, the example output termination network 206, the example compensation network 208, the example control circuitry 210, the example sampling switches 212₁-212_{D}, or, more generally, the example DAC 200 of FIG. 2, could be implemented by programmable circuitry in combination with one or more machine-readable instructions (for example, firmware or software), processor circuitry, analog circuit(s), digital circuit(s), logic circuit(s), programmable processor(s), programmable microcontroller(s), graphics processing unit(s) (GPU(s)), digital signal processor(s) (DSP(s)), ASIC(s), programmable logic device(s) (PLD(s)), or field programmable logic device(s) (FPLD(s)) such as FPGAs. Further still, the example DAC 200 of FIG. 2 may include one or more elements, processes, or devices in addition to, or instead of, those illustrated in FIG. 2, or may include more than one of any or all of the illustrated elements, processes, and devices.

“Including” and “comprising” (and all forms and tenses thereof) are used herein to be open ended terms. Thus, whenever a claim employs any form of “include” or “comprise” (for example, comprises, includes, comprising, including, having, etc.) as a preamble or within a claim recitation of any kind, additional elements, terms, etc., may be present without falling outside the scope of the corresponding claim or recitation. As used herein, when the phrase “at least” is used as the transition term in, for example, a preamble of a claim, it is open-ended in the same manner as the term “comprising” and “including” are open ended. As used herein in the context of describing structures, components, items, objects and things, the phrase “at least one of A and B” refers to implementations including any of (1) at least one A, (2) at least one B, or (3) at least one A and at least one B. Similarly, as used herein in the context of describing structures, components, items, objects and things, the phrase “at least one of A or B” refers to implementations including any of (1) at least one A, (2) at least one B, or (3) at least one A and at least one B. As used herein in the context of describing the performance or execution of processes, instructions, actions, activities, etc., the phrase “at least one of A and B” refers to implementations including any of (1) at least one A, (2) at least one B, or (3) at least one A and at least one B. Similarly, as used herein in the context of describing the performance or execution of processes, instructions, actions, activities, etc., the phrase “at least one of A or B” refers to implementations including any of (1) at least one A, (2) at least one B, or (3) at least one A and at least one B.

As used herein, singular references (for example, “a,” “an,” “first,” “second,” etc.) do not exclude a plurality. The term “a” or “an” object, as used herein, refers to one or more of that object. The terms “a” (or “an”), “one or more,” and “at least one” are used interchangeably herein. Furthermore, although individually listed, a plurality of means, elements, or actions may be implemented by, for example, the same entity or object. Also, although individual features may be included in different examples or claims, these may possibly be combined, and the inclusion in different examples or claims does not imply that a combination of features is at least one of not feasible or advantageous.

As used herein, connection references (for example, attached, coupled, connected, and joined) may include intermediate members between the elements referenced by at least one of the connection reference or relative movement between those elements unless otherwise indicated. As such, connection references do not necessarily infer that two elements are directly connected or in fixed relation to each other.

Unless specifically stated otherwise, descriptors such as “first,” “second,” “third,” “fourth,” “fifth,” “sixth,” “seventh,” “eighth,” “ninth,” etc., are used herein without imputing or otherwise indicating any meaning of priority, physical order, arrangement in a list, or ordering in any way, but are merely used as at least one of labels or arbitrary names to distinguish elements for ease of understanding the described examples. In some examples, the descriptor “first” may be used to refer to an element in the detailed description, while the same element may be referred to in a claim with a different descriptor such as “second” or “third.” In such instances, such descriptors are used merely for identifying those elements distinctly within the context of the description (for example, within a claim) in which the elements might, for example, otherwise share a same name.

As used herein, the phrase “in communication,” including variations thereof, encompasses one of or a combination of direct communication or indirect communication through one or more intermediary components, and does not require direct physical (for example, wired) communication or constant communication, but rather also includes selective communication at least one of periodic intervals, scheduled intervals, aperiodic intervals, or one-time events.

As used herein, “programmable circuitry” is defined to include at least one of (i) one or more special purpose electrical circuits (for example, an application specific circuit (ASIC)) structured to perform specific operation(s) and including one or more semiconductor-based logic devices (for example, electrical hardware implemented by one or more transistors), or (ii) one or more general purpose semiconductor-based electrical circuits programmable with instructions to perform one or more specific functions(s) or operation(s) and including one or more semiconductor-based logic devices (for example, electrical hardware implemented by one or more transistors). Examples of programmable circuitry include programmable microprocessors such as Central Processor Units (CPUs) that may execute first instructions to perform one or more operations or functions, Field Programmable Gate Arrays (FPGAs) that may be programmed with second instructions to at least one of configure or structure the FPGAs to instantiate one or more operations or functions corresponding to the first instructions, Graphics Processor Units (GPUs) that may execute first instructions to perform one or more operations or functions, Digital Signal Processors (DSPs) that may execute first instructions to perform one or more operations or functions, XPUs, Network Processing Units (NPUs) one or more microcontrollers that may execute first instructions to perform one or more operations or functions or integrated circuits such as Application Specific Integrated Circuits (ASICs). For example, an XPU may be implemented by a heterogeneous computing system including multiple types of programmable circuitry (for example, one or more FPGAs, one or more CPUs, one or more GPUs, one or more NPUs, one or more DSPs, etc., and any combination(s) thereof), and orchestration technology (for example, application programming interface(s) (API(s)) that may assign computing task(s) to whichever one(s) of the multiple types of programmable circuitry is/are suited and available to perform the computing task(s).

As used herein, integrated circuit/circuitry is defined as one or more semiconductor packages containing one or more circuit elements such as transistors, capacitors, inductors, resistors, current paths, diodes, etc. For example, an integrated circuit may be implemented as one or more of an ASIC, an FPGA, a chip, a microchip, programmable circuitry, a semiconductor substrate coupling multiple circuit elements, a system on chip (SoC), etc.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

A device that is “configured to” perform a task or function may be configured (for example, at least one of programmed or hardwired) at a time of manufacturing by a manufacturer to at least one of perform the function or be configurable (or re-configurable) by a user after manufacturing to perform the function/or other additional or alternative functions. The configuring may be through at least one of firmware or software programming of the device, through at least one of a construction or layout of hardware components and interconnections of the device, or a combination thereof.

As used herein, the terms “terminal,” “node,” “interconnection,” “pin” and “lead” are used interchangeably. Unless specifically stated to the contrary, these terms are generally used to mean an interconnection between or a terminus of a device element, a circuit element, an integrated circuit, a device or other electronics or semiconductor component.

In the description and claims, described “circuitry” may include one or more circuits. A circuit or device that is described herein as including certain components may instead be adapted to be coupled to those components to form the described circuitry or device. For example, a structure described as including one or more semiconductor elements (such as transistors), one or more passive elements (such as one of or a combination of resistors, capacitors, or inductors), or one or more sources (such as at least one of voltage sources or current sources) may instead include only the semiconductor elements within a single physical device (for example, at least one of a semiconductor die or integrated circuit (IC) package) and may be adapted to be coupled to at least some of the passive elements or the sources to form the described structure either at a time of manufacture or after a time of manufacture, for example, by at least one of an end-user or a third-party.

Circuits described herein are reconfigurable to include the replaced components to provide functionality at least partially similar to functionality available prior to the component replacement. Components shown as resistors, unless otherwise stated, are generally representative of any one or more elements coupled in at least one of series or parallel to provide an amount of impedance represented by the shown resistor. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor. While certain elements of the described examples are included in an integrated circuit and other elements are external to the integrated circuit, in other examples, additional or fewer features may be incorporated into the integrated circuit. In addition, some or all of the features illustrated as being external to the integrated circuit may be included in the integrated circuit and some features illustrated as being internal to the integrated circuit may be incorporated outside of the integrated. As used herein, the term “integrated circuit” means one or more circuits that are at least one of: (i) incorporated in/over a semiconductor substrate; (ii) incorporated in a single semiconductor package; (iii) incorporated into the same module; or (iv) incorporated in/on the same printed circuit board.

Uses of the phrase “ground” in the foregoing description include at least one of a chassis ground, an Earth ground, a floating ground, a virtual ground, a digital ground, a common ground, or any other form of ground connection applicable to, or suitable for, the teachings of this description. As used herein, “approximately,” “about,” and “substantially” modify their subjects/values to recognize the potential presence of variations that occur in real world applications. As used herein, “approximately,” “about,” and “substantially” modify their subjects/values to recognize the potential presence of variations that occur in real world applications. For example, “approximately,” “about,” and “substantially” may modify at least one of dimensions or values that may not be exact due to at least one of manufacturing tolerances or other real-world imperfections. Unless otherwise stated, “about,” “approximately,” or “substantially” preceding a value means+/−10 percent of the stated value, or, if the value is zero, a reasonable range of values around zero.

Modifications are possible in the described examples, and other examples are possible, within the scope of the claims.

From the foregoing, it will be appreciated that example systems, apparatus, articles of manufacture, and methods have been described that include a compensation network that provides a target SFDR level across a wide frequency range in a time-interleaved DAC. For a wideband time-interleaved DAC, the example compensation network senses an analog signal at the output of the time-interleaved DAC and cancels odd harmonics (IMD₃ and HD₃ components) of interleaving spurs. For example, the example compensation network cancels the relative phase shift between (1) the IMD₃ and HD₃ components generated by example cancellation circuits and (2) the IMD₃ and HD₃ components present in an analog signal produced by the time-interleaved DAC.

Also, for example, the example compensation network provides additional compensation in specific frequency ranges. For example, in the second frequency range (zone 2: 3 GHz-6 GHz), example LC circuits of the compensation network provide additional compensation in addition to the compensation provided by example cancellation circuits of the compensation network. In examples described herein, an example pole-zero pair of the example LC circuits sets the frequency range in which additional compensation is provided. In examples described herein, the position of the example pole-zero pair in the frequency spectrum can be adjusted using programmable components. As such, the frequency range in which additional compensation is provided is adjustable. In examples described herein, the frequency range is set to 3 GHz to 6 GHz (the frequency range in which third-order harmonics are present). In other frequency ranges (zone 1: 0 Hz-3 GHz and zone 3: 6 GHz to 18 GHz), the phase shift induced by the example LC circuits of the compensation network becomes zero. As such, the example compensation network provides compensation for non-linearities in an analog signal provided a time-interleaved DAC across the bandwidth of the interleaved DAC.

Described systems, apparatus, articles of manufacture, and methods improve the efficiency of using a computing device by increasing the SFDR of an interleaved DAC. For example, examples described herein include a single compensation network at the output of an interleaved DAC to compensate for non-linearities in an analog signal provided by the interleaved DAC. As such, the single compensation network provides compensation across the frequency bandwidth of the interleaved DAC without any trim setting changes allowing the interleaved DAC to scan the entire bandwidth (0 Hz to 18 GHz) simultaneously. Also, by implementing the example compensation network once at the output of the time-interleaved DAC, the example compensation network is area efficient. As such, examples described herein can be implemented with reduced layout complexity. Described systems, apparatus, articles of manufacture, and methods are also directed to one or more improvement(s) in the operation of a machine such as a computer or other electronic, electromechanical, or mechanical device.

What is claimed is:

1. An apparatus comprising:
a multiplexer having a first output and a second output;
a first capacitor having a first terminal and a second terminal coupled to the first output of the multiplexer;
a first lead compensator (LC) circuit having an output and an input coupled to the first terminal of the first capacitor;
a first resistor having a first terminal coupled to the output of the first LC circuit and a second terminal coupled to a first supply terminal;
a first transistor having a control terminal, a first terminal, and a second terminal, the control terminal coupled to the output of the first LC circuit, the second terminal coupled to a ground terminal;
a second transistor having a control terminal coupled to a second supply terminal, a first terminal coupled to the second output of the multiplexer, and a second terminal coupled to the first terminal of the first transistor;
a first current source circuit having an output coupled to the ground terminal and an input coupled to the second terminal of the second transistor;
a second capacitor having a first terminal and a second terminal coupled to the second output of the multiplexer;
a second LC circuit having an output and an input coupled to the first terminal of the second capacitor;
a second resistor having a first terminal coupled to the output of the second LC circuit and a second terminal coupled to the first supply terminal;
a third transistor having a control terminal, a first terminal, and a second terminal, the control terminal coupled to the output of the second LC circuit, the second terminal coupled to the ground terminal;
a fourth transistor having a control terminal coupled to the second supply terminal, a first terminal coupled to the first output of the multiplexer, and a second terminal coupled to the first terminal of the third transistor; and
a second current source circuit having an output coupled to the ground terminal and an input coupled to the second terminal of the fourth transistor.

2. The apparatus of claim 1, wherein respective ones of the first LC circuit and the second LC circuit include:
a third capacitor having a first terminal to operate as the output of the respective ones of the first LC circuit and the second LC circuit and a second terminal to operate as the input of the respective ones of the first LC circuit and the second LC circuit;
a third resistor having a first terminal and a second terminal coupled to the first terminal of the third capacitor;
a fourth resistor having a first terminal coupled to the first terminal of the third resistor and a second terminal coupled to the first supply terminal;
a fourth capacitor having a first terminal coupled to the ground terminal and a second terminal coupled to the first terminal of the third resistor; and
a fifth capacitor having a first terminal coupled to the ground terminal and a second terminal coupled to the first terminal of the third capacitor.

3. The apparatus of claim 2, wherein the third resistor is a variable resistor, and the fourth capacitor is a variable capacitor.

4. The apparatus of claim 1, further including:
a third capacitor having a first terminal and a second terminal coupled to the first output of the multiplexer;
a third LC circuit having an output and an input coupled to the first terminal of the third capacitor;
a third resistor having a first terminal coupled to the output of the third LC circuit and a second terminal coupled to a third supply terminal;
a fifth transistor having a control terminal, a first terminal, and a second terminal, the control terminal coupled to the output of the third LC circuit, the second terminal coupled to the ground terminal;
a sixth transistor having a control terminal coupled to a fourth supply terminal, a first terminal coupled to the second output of the multiplexer, and a second terminal coupled to the first terminal of the fifth transistor;
a fourth capacitor having a first terminal coupled to the ground terminal and a second terminal coupled to the second terminal of the sixth transistor;
a third current source circuit having an output coupled to the ground terminal and an input coupled to the second terminal of the sixth transistor;
a fifth capacitor having a first terminal and a second terminal coupled to the second output of the multiplexer;
a fourth LC circuit having an output and an input coupled to the first terminal of the fifth capacitor;
a fourth resistor having a first terminal coupled to the output of the fourth LC circuit and a second terminal coupled to the third supply terminal;
a seventh transistor having a control terminal, a first terminal, and a second terminal, the control terminal coupled to the output of the fourth LC circuit, the second terminal coupled to the ground terminal;
an eighth transistor having a control terminal coupled to the fourth supply terminal, a first terminal coupled to the first output of the multiplexer, and a second terminal coupled to the first terminal of the seventh transistor;
a sixth capacitor having a first terminal coupled to the ground terminal and a second terminal coupled to the second terminal of the eighth transistor; and
a fourth current source circuit having an output coupled to the ground terminal and an input coupled to the second terminal of the eighth transistor.

5. The apparatus of claim 1, wherein a first current through the second transistor and a second current through the fourth transistor are to compensate for a third-order intermodulation distortion component and a third-order harmonic distortion component of an analog signal from 0 hertz to 3 gigahertz, the analog signal to be measured between the first output and the second output of the multiplexer.

6. The apparatus of claim 1, wherein a first current through the second transistor, a second current through the fourth transistor, a first phase caused by the first LC circuit, and a second phase caused by the second LC circuit are to compensate for at least one of a third-order intermodulation distortion component or a third-order harmonic distortion component of an analog signal from 3 gigahertz (GHz) to 6 GHz, the analog signal to be measured between the first output and the second output of the multiplexer.

7. The apparatus of claim 1, wherein a first current through the second transistor and a second current through the fourth transistor are to compensate for a third-order intermodulation distortion component of an analog signal from 6 gigahertz (GHz) to 18 GHz, the analog signal to be measured between the first output and the second output of the multiplexer.

8. A digital-to-analog converter (DAC) comprising:
control circuitry having a first terminal, a second terminal, a third terminal, and a fourth terminal;
a first switch having a control terminal, a first terminal, and a second terminal, the control terminal coupled to the first terminal of the control circuitry;
a first DAC core having a positive output, a negative output, and an input coupled to the second terminal of the first switch;
a second switch having a control terminal, a first terminal, and a second terminal, the control terminal coupled to the second terminal of the control circuitry, the first terminal coupled to the first terminal of the first switch;
a second DAC core having a positive output, a negative output, and an input coupled to the second terminal of the second switch;
a multiplexer having a positive output, a negative output, a first positive input coupled to the positive output of the first DAC core, a first negative input coupled to the negative output of the first DAC core, a second positive input coupled to the positive output of the second DAC core, a second negative input coupled to the negative output of the second DAC core, a first control terminal coupled to the third terminal of the control circuitry, and a second control terminal coupled to the fourth terminal of the control circuitry;
an output termination network having a positive input coupled to the positive output of the multiplexer and a negative input coupled to the negative output of the multiplexer; and
a compensation network having a positive input coupled to the positive output of the multiplexer, a negative input coupled to the negative output of the multiplexer, a positive supply terminal coupled to the negative output of the multiplexer, and a negative supply terminal coupled to the positive output of the multiplexer.

9. The DAC of claim 8, wherein respective ones of the first DAC core and the second DAC core include:
a first capacitor having a first terminal and a second terminal;
a second capacitor having a first terminal coupled to a ground terminal and a second terminal coupled to the first terminal of the first capacitor;
a first transistor having a control terminal, a first terminal, and a second terminal, the control terminal coupled to the first terminal of the first capacitor, the first terminal to operate as the positive output of the respective ones of the first DAC core and the second DAC core;
a first resistor having a first terminal coupled to the ground terminal and a second terminal coupled to the second terminal of the first transistor;
an inverter having an output and an input coupled to the second terminal of the first capacitor, the second terminal of the first capacitor and the input of the inverter to operate as the input of the respective ones of the first DAC core and the second DAC core;
a third capacitor having a first terminal and a second terminal coupled to the output of the inverter;
a fourth capacitor having a first terminal coupled to the ground terminal and a second terminal coupled to the first terminal of the third capacitor;
a second transistor having a control terminal, a first terminal, and a second terminal, the control terminal coupled to the first terminal of the third capacitor, the first terminal to operate as the negative output of the respective ones of the first DAC core and the second DAC core; and
a second resistor having a first terminal coupled to the ground terminal and a second terminal coupled to the second terminal of the second transistor.

10. The DAC of claim 8, wherein the multiplexer includes:
a first cell having a positive output, a negative output, a positive input to operate as the first positive input of the multiplexer, a negative input to operate as the first negative input of the multiplexer, and a control terminal to operate as the first control terminal of the multiplexer; and
a second cell having a positive output, a negative output, a positive input to operate as the second positive input of the multiplexer, a negative input to operate as the second negative input of the multiplexer, and a control terminal to operate as the second control terminal of the multiplexer, the positive output of the first cell and the positive output of the second cell to operate as the positive output of the multiplexer, the negative output of the first cell and the negative output of the second cell to operate as the negative output of the multiplexer, respective ones of the first cell and the second cell including:
a first transistor having a control terminal, a first terminal to operate as the positive output of the respective ones of the first cell and the second cell, and a second terminal to operate as the positive input of the respective ones of the first cell and the second cell; and
a second transistor having a control terminal coupled to the control terminal of the first transistor, a first terminal to operate as the negative output of the respective ones of the first cell and the second cell, and a second terminal to operate as the negative input of the respective ones of the first cell and the second cell, the control terminal of the first transistor and the control terminal of the second transistor to operate as the control terminal of the respective ones of the first cell and the second cell.

11. The DAC of claim 8, wherein the output termination network includes:
a first resistor having a first terminal and a second terminal coupled to a supply terminal;
a second resistor having a first terminal to operate as the positive input of the output termination network and a second terminal coupled to the first terminal of the first resistor; and
a third resistor having a first terminal to operate as the negative input of the output termination network and a second terminal coupled to the first terminal of the first resistor.

12. The DAC of claim 8, wherein the compensation network includes:
a first capacitor having a first terminal and a second terminal to operate as the positive input of the compensation network;
a first lead compensator (LC) circuit having an output and an input coupled to the first terminal of the first capacitor;
a first resistor having a first terminal coupled to the output of the first LC circuit and a second terminal coupled to a first supply terminal;
a first transistor having a control terminal, a first terminal, and a second terminal, the control terminal coupled to the output of the first LC circuit, the second terminal coupled to a ground terminal;
a second transistor having a control terminal coupled to a second supply terminal, a first terminal to operate at the positive supply terminal of the compensation network, and a second terminal coupled to the first terminal of the first transistor;
a first current source circuit having an output coupled to the ground terminal and an input coupled to the second terminal of the second transistor;
a second capacitor having a first terminal and a second terminal to operate as the negative input of the compensation network;
a second LC circuit having an output and an input coupled to the first terminal of the second capacitor;
a second resistor having a first terminal coupled to the output of the second LC circuit and a second terminal coupled to the first supply terminal;
a third transistor having a control terminal, a first terminal, and a second terminal, the control terminal coupled to the output of the second LC circuit, the second terminal coupled to the ground terminal;
a fourth transistor having a control terminal coupled to the second supply terminal, a first terminal to operate as the negative supply terminal of the compensation network, and a second terminal coupled to the first terminal of the third transistor; and
a second current source circuit having an output coupled to the ground terminal and an input coupled to the second terminal of the fourth transistor.

13. The DAC of claim 12, wherein the compensation network further includes:
a third capacitor having a first terminal and a second terminal coupled to the second terminal of the first capacitor;
a third LC circuit having an output and an input coupled to the first terminal of the third capacitor;
a third resistor having a first terminal coupled to the output of the third LC circuit and a second terminal coupled to a third supply terminal;
a fifth transistor having a control terminal, a first terminal, and a second terminal, the control terminal coupled to the output of the third LC circuit, the second terminal coupled to the ground terminal;
a sixth transistor having a control terminal coupled to a fourth supply terminal, a first terminal coupled to the first terminal of the second transistor, and a second terminal coupled to the first terminal of the fifth transistor;
a fourth capacitor having a first terminal coupled to the ground terminal and a second terminal coupled to the second terminal of the sixth transistor;
a third current source circuit having an output coupled to the ground terminal and an input coupled to the second terminal of the sixth transistor;
a fifth capacitor having a first terminal and a second terminal coupled to the second terminal of the second capacitor;
a fourth LC circuit having an output and an input coupled to the first terminal of the fifth capacitor;
a fourth resistor having a first terminal coupled to the output of the fourth LC circuit and a second terminal coupled to the third supply terminal;
a seventh transistor having a control terminal, a first terminal, and a second terminal, the control terminal coupled to the output of the fourth LC circuit, the second terminal coupled to the ground terminal;
an eighth transistor having a control terminal coupled to the fourth supply terminal, a first terminal coupled to the first terminal of the fourth transistor, and a second terminal coupled to the first terminal of the seventh transistor;
a sixth capacitor having a first terminal coupled to the ground terminal and a second terminal coupled to the second terminal of the eighth transistor; and
a fourth current source circuit having an output coupled to the ground terminal and an input coupled to the second terminal of the eighth transistor.

14. The DAC of claim 13, wherein respective ones of the first LC circuit, the second LC circuit, the third LC circuit, and the fourth LC circuit include:
a seventh capacitor having a first terminal to operate as the output of the respective ones of the first LC circuit, the second LC circuit, the third LC circuit, and the fourth LC circuit and a second terminal to operate as the input of the respective ones of the first LC circuit, the second LC circuit, the third LC circuit, and the fourth LC circuit;
a fifth resistor having a first terminal and a second terminal coupled to the first terminal of the seventh capacitor;
a sixth resistor having a first terminal coupled to the first terminal of the fifth resistor and a second terminal coupled to one of the first supply terminal or the second supply terminal;
an eighth capacitor having a first terminal coupled to the ground terminal and a second terminal coupled to the first terminal of the fifth resistor; and
a ninth capacitor having a first terminal coupled to the ground terminal and a second terminal coupled to the first terminal of the seventh capacitor.

15. An apparatus comprising:
a multiplexer having a positive output and a negative output;
a first capacitor having a first terminal and a second terminal coupled to the positive output of the multiplexer;
a first lead compensator (LC) circuit having an output and an input coupled to the first terminal of the first capacitor;
a second capacitor having a first terminal and a second terminal coupled to the positive output of the multiplexer;
a second LC circuit having an output and an input coupled to the first terminal of the second capacitor;
a first cancellation circuit having a first input coupled to the output of the first LC circuit, a second input coupled to the output of the second LC circuit, a first voltage terminal coupled to the negative output of the multiplexer, and a second voltage terminal coupled to a ground terminal;
a third capacitor having a first terminal and a second terminal coupled to the negative output of the multiplexer;
a third LC circuit having an output and an input coupled to the first terminal of the third capacitor;
a fourth capacitor having a first terminal and a second terminal coupled to the negative output of the multiplexer;
a fourth LC circuit having an output and an input coupled to the first terminal of the fourth capacitor; and
a second cancellation circuit having a first input coupled to the output of the third LC circuit, a second input coupled to the output of the fourth LC circuit, a first voltage terminal coupled to the positive output of the multiplexer, and a second voltage terminal coupled to the ground terminal.

16. The apparatus of claim 15, wherein respective ones of the first LC circuit, the second LC circuit, the third LC circuit, and the fourth LC circuit include:
a fifth capacitor having a first terminal to operate as the output of the respective ones of the first LC circuit, the second LC circuit, the third LC circuit, and the fourth LC circuit and a second terminal to operate as the input of the respective ones of the first LC circuit, the second LC circuit, the third LC circuit, and the fourth LC circuit;
a first resistor having a first terminal and a second terminal coupled to the first terminal of the fifth capacitor;
a second resistor having a first terminal coupled to the first terminal of the first resistor and a second terminal coupled to a supply terminal;
a sixth capacitor having a first terminal coupled to the ground terminal and a second terminal coupled to the first terminal of the first resistor; and
a seventh capacitor having a first terminal coupled to the ground terminal and a second terminal coupled to the first terminal of the sixth capacitor.

17. The apparatus of claim 16, wherein the first resistor is a variable resistor, and the sixth capacitor is a variable capacitor.

18. The apparatus of claim 15, wherein the first cancellation circuit and the second cancellation circuit are to compensate for a third-order intermodulation distortion component and a third-order harmonic distortion component of an analog signal from 0 hertz to 3 gigahertz, the analog signal to be measured between the positive output and the negative output of the multiplexer.

19. The apparatus of claim 15, wherein the first cancellation circuit, the second cancellation circuit, the first LC circuit, the second LC circuit, the third LC circuit, and the fourth LC circuit are to compensate for at least one of a third-order intermodulation distortion component or a third-order harmonic distortion component of an analog signal from 3 gigahertz (GHz) to 6 GHz, the analog signal to be measured between the positive output and the negative output of the multiplexer.

20. The apparatus of claim 15, wherein the first cancellation circuit and the second cancellation circuit are to compensate for a third-order intermodulation distortion component of an analog signal from 6 gigahertz (GHz) to 18 GHz, the analog signal to be measured between the positive output and the negative output of the multiplexer.
